(19) United States
(12) Patent Application Publication
(10) Pub. No.: US 2026/0025987 A1
(43) Pub. Date: Jan. 22, 2026

(54) ACCESS LINE PARTITION OUTSIDE ARRAY FOR THREE DIMENSIONAL (3D) MEMORY

(71) Applicant: Micron Technology, Inc., Boise, ID (US)

(72) Inventors: Benben Li, Boise, ID (US); Cheng Li, Boise, ID (US)

(21) Appl. No.: 19/263,015

(22) Filed: Jul. 8, 2025

Related U.S. Application Data
(60) Provisional application No. 63/672,092, filed on Jul. 16, 2024.

(51) Int. Cl. H10B 12/00

(52) U.S. Cl. CPC H10B 12/488; H10B 12/02

(57) ABSTRACT

Systems, methods, and apparatus are provided for access line structures for an access line partition outside an array for three dimensional (3D) memory. Forming the access line structures includes forming horizontally oriented access devices and horizontally oriented storage nodes in a plurality of levels of the vertically stacked 3D memory array, forming a first vertical opening through the vertically stacked 3D memory array, depositing a doped silicon (Si) material in the first vertical opening, selectively removing portions of the doped Si material in an array region, selectively removing portions of the doped Si in a patch isolation region separating the array region from a peripheral component region of the vertically stacked 3D memory array, selectively removing portions of the continuous horizontal access lines in the patch isolation region, and replacing the removed portions of the continuous horizontal access lines with a first dielectric material in the patch isolation region.

### PRIORITY INFORMATION

This application claims the benefits of U.S. Provisional Application No. 63/672,092, filed on Jul. 16, 2024, the contents of which are incorporated herein by reference.

### TECHNICAL FIELD

The present disclosure relates generally to memory devices, and more particularly, to an access line partition outside an array for three dimensional (3D) memory

### BACKGROUND

Memory is often implemented in electronic systems, such as computers, cell phones, hand-held devices, etc. There are many different types of memory, including volatile and non-volatile memory. Volatile memory may require power to maintain its data and may include random-access memory (RAM), dynamic random-access memory (DRAM), static random-access memory (SRAM), and synchronous dynamic random-access memory (SDRAM). Non-volatile memory may provide persistent data by retaining stored data when not powered and may include NAND flash memory, NOR flash memory, nitride read only memory (NROM), phase-change memory (e.g., phase-change random access memory), resistive memory (e.g., resistive random-access memory), cross-point memory, ferroelectric random-access memory (FeRAM), or the like.

As design rules shrink, less semiconductor space is available to fabricate memory, including DRAM arrays. A respective memory cell for DRAM may include an access device, e.g., transistor, having a first and a second source/drain region separated by a channel region. A gate may oppose the channel region and be separated therefrom by a gate dielectric. An access line, such as a word line, is electrically connected to the gate of the DRAM memory cell. A DRAM memory cell can include a storage node, such as a capacitor cell, coupled by the access device to a sense line, such as a digit line. The access device can be activated (e.g., to select the cell) by an access line coupled to the access device. The capacitor can store a charge corresponding to a data value of a respective memory cell (e.g., a logic “1” or “0”).

### BRIEF DESCRIPTION OF THE DRAWINGS

FIG. 1A is a schematic illustration of an array of memory cells in a vertical three dimensional (3D) memory, in accordance with a number of embodiments of the present disclosure.

FIG. 1B is a perspective view illustrating a portion of a three dimensional (3D) semiconductor memory device, in accordance with a number of embodiments of the present disclosure.

FIG. 2 illustrates a portion of a horizontal access device in vertical three dimensional (3D) memory, in accordance with a number of embodiments of the present disclosure.

FIG. 3 is a perspective view illustrating horizontal access devices, in accordance with a number of embodiments of the present disclosure.

FIG. 4 is a cross-sectional view of a vertical stack in vertical three dimensional (3D) memory, in accordance with a number of embodiments of the present disclosure.

FIGS. 5A to 5B illustrate an example method at one stage of a semiconductor fabrication process for forming an access line partition outside of a 3D memory array for a memory device, in accordance with a number of embodiments of the present disclosure.

FIGS. 6A to 6D illustrate an example method at another stage of a semiconductor fabrication process for forming an access line partition outside of a 3D memory array for a memory device, in accordance with a number of embodiments of the present disclosure.

FIGS. 7A to 7B illustrate an example method at another stage of a semiconductor fabrication process for forming an access line partition outside of a 3D memory array for a memory device, in accordance with a number of embodiments of the present disclosure.

FIG. 8 illustrates an example method at another stage of a semiconductor fabrication process for forming an access line partition outside of a 3D memory array for a memory device, in accordance with a number of embodiments of the present disclosure.

FIG. 9 illustrates an example method at another stage of a semiconductor fabrication process for forming an access line partition outside of a 3D memory array for a memory device, in accordance with a number of embodiments of the present disclosure.

FIGS. 10A to 10B illustrate an example method at another stage of a semiconductor fabrication process for forming an access line partition outside of a 3D memory array for a memory device, in accordance with a number of embodiments of the present disclosure.

FIGS. 11A to 11B illustrate an example method at another stage of a semiconductor fabrication process for forming an access line partition outside of a 3D memory array for a memory device, in accordance with a number of embodiments of the present disclosure.

FIGS. 12A to 12B illustrate an example method at another stage of a semiconductor fabrication process for forming an access line partition outside of a 3D memory array for a memory device, in accordance with a number of embodiments of the present disclosure.

FIGS. 13A to 13B illustrate an example method at another stage of a semiconductor fabrication process for forming an access line partition outside of a 3D memory array for a memory device, in accordance with a number of embodiments of the present disclosure.

FIGS. 14A to 14B illustrate an example method at another stage of a semiconductor fabrication process for forming an access line partition outside of a 3D memory array for a memory device, in accordance with a number of embodiments of the present disclosure.

FIGS. 15A to 15B illustrate an example method at another stage of a semiconductor fabrication process for forming an access line partition outside of a 3D memory array for a memory device, in accordance with a number of embodiments of the present disclosure.

FIGS. 16A to 16B illustrate an example method at another stage of a semiconductor fabrication process for forming an access line partition outside of a 3D memory array for a memory device, in accordance with a number of embodiments of the present disclosure.

FIGS. 17A to 17B illustrate an example method at another stage of a semiconductor fabrication process for forming an access line partition outside of a 3D memory array for a memory device, in accordance with a number of embodiments of the present disclosure.

FIGS. 18A to 18B illustrate an example method at another stage of a semiconductor fabrication process for forming an access line partition outside of a 3D memory array for a memory device, in accordance with a number of embodiments of the present disclosure.

FIGS. 19A to 19B illustrate an example method at another stage of a semiconductor fabrication process for forming an access line partition outside of a 3D memory array for a memory device, in accordance with a number of embodiments of the present disclosure.

FIG. 20 is a block diagram of an apparatus in the form of a computing system including a memory device in accordance with a number of embodiments of the present disclosure.

### DETAILED DESCRIPTION

Embodiments of the present disclosure describe forming an access line partition outside of a 3D memory array for a memory device. Horizontally oriented access devices and horizontally oriented storage nodes are formed in a plurality of levels as memory cells in a vertically stacked 3D memory array that has continuous, conductive horizontal access lines at each level that serve as gates at channel regions separating first and second source/drain regions of the horizontal access devices. A first vertical opening is formed through the vertically stacked 3D memory array extending predominantly in a first horizontal direction to expose first vertical sidewalls in the 3D memory array. A doped silicon (Si) material is deposited in the first vertical opening and portions of the doped Si are selectively removed in an array region to form a plurality of spaced, vertical sense lines in the array region that are electrically coupled to the first source/drain regions in the array region. Portions of the doped Si are selectively removed from the patch isolation region which separates array regions of the vertically stacked 3D memory array. Further, portions of the continuous horizontal access lines in the patch isolation region are removed and replaced with a first dielectric material. As used herein, the term “continuous, conductive horizontal access line” can refer to a conductive material that is deposited on multiple levels of a vertical stack as an access line, wherein the conductive material is deposited such that there are no gaps in the conductive material that would electrically isolate any portion of the conductive material from another portion of the conductive material.

When the horizontally oriented access lines are formed this way, the different levels of the vertical stack can be connected to each other due to the continuous access line material overflowing to different levels of the memory in an array region of the memory array. This overflow can cause the access lines of the different levels to be electrically connected to each other which could result in the memory device not being able to activate any of the horizontally oriented access lines individually. This can result in the horizontally oriented access lines being shorted to each other when any of the horizontally oriented access lines are activated. As used herein, activating a horizontally oriented access line can involve providing current to a horizontally oriented access line such that a memory cell coupled to that horizontally oriented access line can be selected.

However, embodiments of the present disclosure can separate the connected horizontally oriented access lines. The connected horizontally oriented access lines can be separated by an etching process in which the portion of the horizontally oriented access line in the patch isolation region is removed and replaced with a dielectric material. This can result in the portion of the horizontally oriented access lines in an array region of a memory array being disconnected from the portion of the horizontally oriented access lines in a different array region of the memory array. Embodiments are not so limited, and the array regions can be peripheral regions or any other type of region in a memory array. This can also result in the horizontally oriented access lines of each level of the memory array being disconnected from each other.

Separating the portion of the horizontally oriented access lines in the array region from the portion of the horizontally oriented access lines in the periphery region as described above provides the benefit of allowing the horizontally oriented access line of each level to be activated individually. Each access line contact can be coupled to a power source such that the power source can provide current and/or voltage to each horizontally oriented access line individually. This improves over previous approaches because this prevents the horizontally oriented access lines from being shorted to each other when a horizontally oriented access line on a level of the memory array is activated.

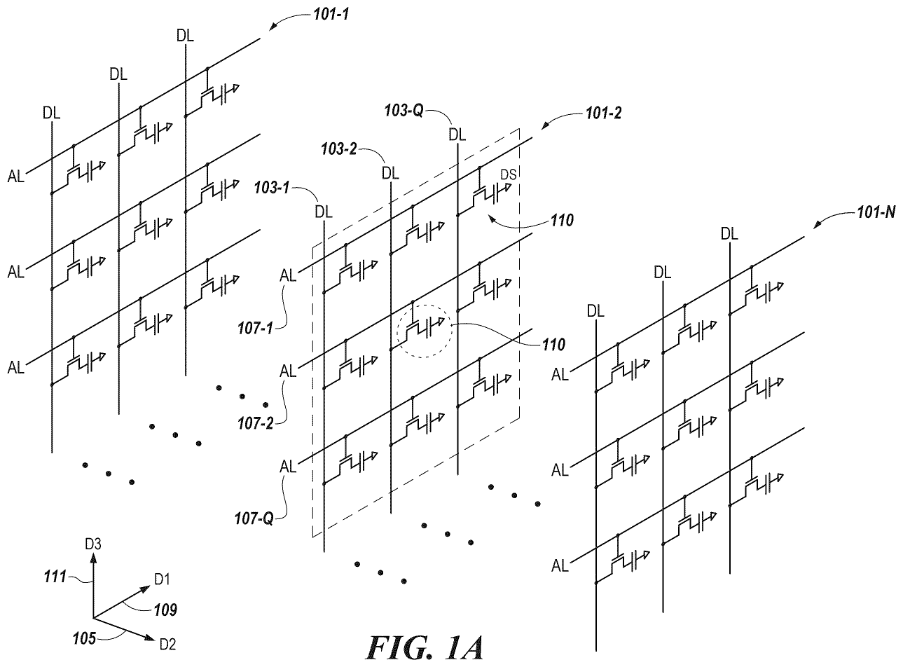

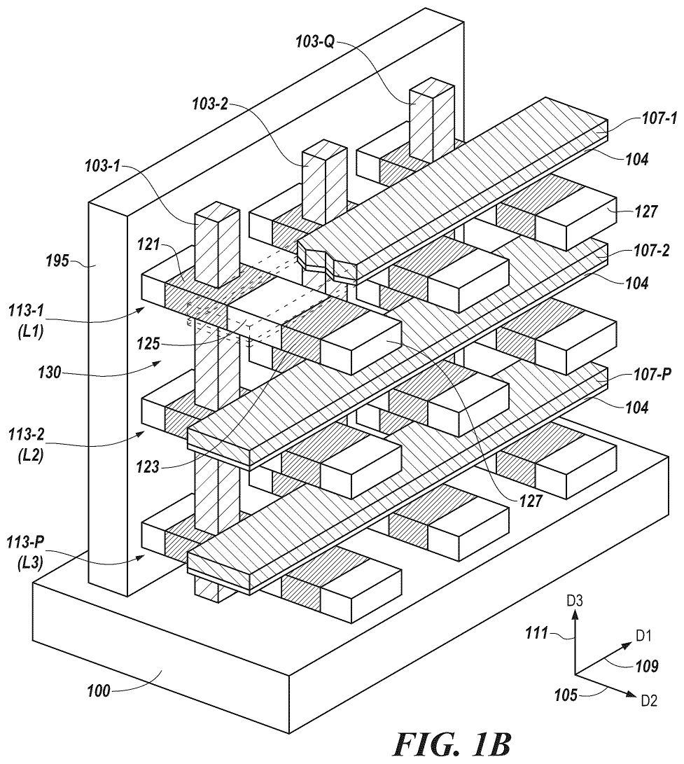

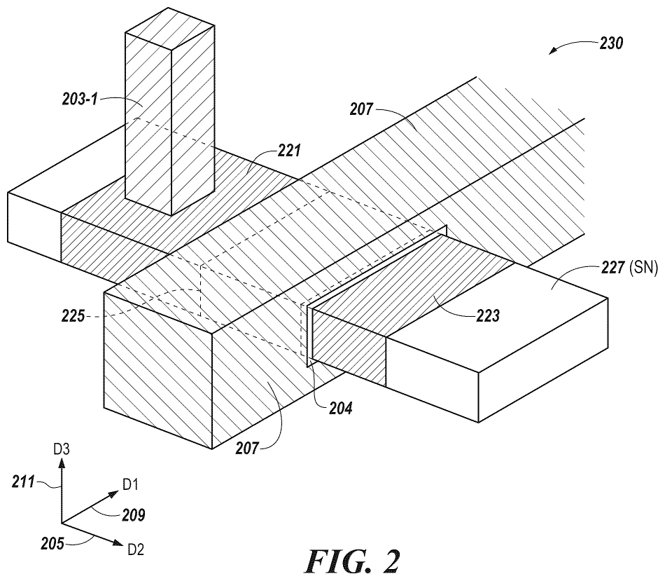

The figures herein follow a numbering convention in which the first digit or digits correspond to the figure number of the drawing and the remaining digits identify an element or component in the drawing. Similar elements or components between different figures may be identified by the use of similar digits. For example, reference numeral 103 may reference element “03” in FIG. 1A, and a similar element may be referenced as 203 in FIG. 2. Multiple analogous elements within one figure may be referenced with a reference numeral followed by a hyphen and another numeral or a letter. For example, 107-1 may reference element 107-1 in FIG. 1A and 107-2 may reference element 107-2, which may be analogous to element 107-1. Such analogous elements may be generally referenced without the hyphen and extra numeral or letter. For example, elements 107-1 and 107-2 or other analogous elements may be generally referenced as 107.

FIG. 1A is a schematic illustration of an array of memory cells in a vertical three dimensional (3D) memory in accordance with a number of embodiments of the present disclosure. FIG. 1A illustrates that a cell array may have a plurality of sub cell arrays 101-1, 101-2, . . . , 101-N. The sub cell arrays 101-1, 101-2, . . . , 101-N may be arranged along a second direction (D2) 105. Each of the sub cell arrays, e.g., sub cell array 101-2, may include a plurality of access lines 107-1, 107-2, . . . , 107-Q (which also may be referred to a word lines). Also, each of the sub cell arrays, e.g., sub cell array 101-2, may include a plurality of digit lines 103-1, 103-2, . . . , 103-Q (which also may be referred to as bit lines, data lines, or sense lines). In FIG. 1A, the access lines 107-1, 107-2, . . . , 107-Q are illustrated extending in a first direction (D1) 109 and the digit lines 103-1, 103-2, . . . , 103-Q are illustrated extending in a third direction (D3) 111. According to embodiments, the first direction (D1) 109 and the second direction (D2) 105 may be considered in a horizontal (“X-Y”) plane. The third direction (D3) 111 may be considered in a vertical (“Z”) plane. Hence, according to embodiments described herein, the digit lines 103-1, 103-2, . . . , 103-Q are extending in a vertical direction, e.g., third direction (D3) 111.

A memory cell, e.g., 110, may include an access device, e.g., access transistor, and a storage node located at an intersection of each access line 107-1, 107-2, . . . , 107-Q and each digit line 103-1, 103-2, . . . , 103-Q. Memory cells may be written to, or read from, using the access lines 107-1, 107-2, . . . , 107-Q and digit lines 103-1, 103-2, . . . , 103-Q. The access lines 107-1, 107-2, . . . , 107-Q may conductively interconnect memory cells along horizontal rows of each sub cell array 101-, 101-2, . . . , 101-N, and the digit lines 103-1, 103-2, . . . , 103-Q may conductively interconnect memory cells along vertical columns of each sub cell array 101-1, 101-2, . . . , 101-N. One memory cell, e.g., 110, may be located between one access line, e.g., 107-2, and one digit line, e.g., 103-2. Each memory cell may be uniquely addressed through a combination of an access line 107-1, 107-2, . . . , 107-Q and a digit line 103-1, 103-2, . . . , 103-Q.

The access lines 107-1, 107-2, . . . , 107-Q may be or include conducting patterns (e.g., metal lines) disposed on and spaced apart from a substrate. The access lines 107-1, 107-2, . . . , 107-Q may extend in a first direction (D1) 109. The access lines 107-1, 107-2, . . . , 107-Q in one sub cell array, e.g., 101-2, may be spaced apart from each other in a vertical direction, e.g., in a third direction (D3) 111.

The digit lines 103-1, 103-2, . . . , 103-Q may be or include conductive patterns (e.g., metal lines) extending in a vertical direction with respect to the substrate, e.g., in a third direction (D3) 111. The digit lines in one sub cell array, e.g., 101-2, may be spaced apart from each other in the first direction (D1) 109.

A gate of a memory cell, e.g., memory cell 110, may be connected to an access line (e.g., 107-2) and a first conductive node (e.g., a first source/drain region) of an access device (e.g., transistor) of the memory cell 110 may be connected to a digit line (e.g., 103-2). Each of the memory cells (e.g., memory cell 110) may be connected to a storage node (e.g., capacitor). A second conductive node (e.g., second source/drain region) of the access device (e.g., transistor) of the memory cell 110 may be connected to the storage node (e.g., capacitor). While first and second source/drain region references are used herein to denote two separate and distinct source/drain regions, it is not intended that the source/drain region referred to as the “first” and/or “second” source/drain regions have some unique meaning. It is intended only that one of the source/drain regions is connected to a digit line (e.g., 103-2) and the other may be connected to a storage node.

FIG. 1B illustrates a perspective view showing a three dimensional (3D) semiconductor memory device (e.g., a portion of a sub cell array 101-2 shown in FIG. 1A as a vertically oriented stack of memory cells in an array) according to some embodiments of the present disclosure.

As shown in FIG. 1B, a substrate 100 may have formed thereon one of the plurality of sub cell arrays (e.g., 101-2) described in connection with FIG. 1A. For example, the substrate 100 may be or include a silicon substrate, a germanium substrate, or a silicon-germanium substrate, etc. Embodiments, however, are not limited to these examples.

As shown in the example embodiment of FIG. 1B, the substrate 100 may have fabricated thereon a vertically oriented stack of memory cells (e.g., memory cell 110 in FIG. 1A) extending in a vertical direction (e.g., third direction (D3) 111). According to some embodiments, the vertically oriented stack of memory cells may be fabricated such that each memory cell (e.g., memory cell 110 in FIG. 1A) is formed on plurality of vertical levels (e.g., a first level (L1), a second level (L2), and a third level (L3)). The repeating, vertical levels, L1, L2, and L3, may be arranged (e.g., “stacked”) a vertical direction (e.g., third direction (D3) 111 shown in FIG. 1A) and may be separated from the substrate 100 by an insulator material. Each of the repeating, vertical levels, L1, L2, and L3 may include a plurality of discrete components (e.g., regions) to the horizontally oriented access devices 130 (e.g., transistors), and storage nodes (e.g., capacitors) including access line 107-1, 107-2, . . . , 107-Q connections and digit line 103-1, 103-2, . . . , 103-Q connections. The plurality of discrete components to the horizontally oriented access devices 130 (e.g., transistors) may be formed in a plurality of iterations of vertically, repeating layers within each level and may extend horizontally in the second direction (D2) 105, analogous to second direction (D2) 105 shown in FIG. 1A.

The plurality of discrete components to the laterally oriented access devices 130 (e.g., transistors) may include a first source/drain region 121 and a second source/drain region 123 separated by a channel region 125, extending laterally in the second direction (D2) 105, and formed in a body of the access devices. In some embodiments, the channel region 125 may include silicon, germanium, silicon-germanium, and/or indium gallium zinc oxide (IGZO). In some embodiments, the first and the second source/drain regions, 121 and 123, can include an n-type dopant region formed in a p-type doped body to the access device to form an n-type conductivity transistor. In some embodiments, the first and the second source/drain regions, 121 and 123, may include a p-type dopant formed within an n-type doped body to the access device to form a p-type conductivity transistor. By way of example, and not by way of limitation, the n-type dopant may include phosphorous (P) atoms and the p-type dopant may include atoms of boron (B) formed in an oppositely doped body region of polysilicon semiconductor material. Embodiments, however, are not limited to these examples.

The storage node 127 (e.g., capacitor) may be connected to one respective end of the access device. As shown in FIG. 1B, the storage node 127 may be connected to the second source/drain region 123 of the access device. The storage node may be or include memory elements capable of storing data. Each of the storage nodes may be a memory element using one of a capacitor, a magnetic tunnel junction pattern, and/or a variable resistance body which includes a phase change material, etc. Embodiments, however, are not limited to these examples. In some embodiments, the storage node associated with each access device of a unit cell (e.g., memory cell 110 in FIG. 1A) may similarly extend in the second direction (D2) 105, analogous to second direction (D2) 105 shown in FIG. 1A.

As shown in FIG. 1B a plurality of horizontally oriented access lines 107-1, 107-2, . . . , 107-Q extend in the first direction (D1) 109, analogous to the first direction (D1) 109 in FIG. 1A. The plurality of horizontally oriented access lines 107-1, 107-2, . . . , 107-Q may be analogous to the access lines 107-1, 107-2, . . . , 107-Q shown in FIG. 1A. The plurality of horizontally oriented access lines 107-1, 107-2, . . . , 107-Q may be arranged (e.g., “stacked”) along the third direction (D3) 111. The plurality of horizontally oriented access lines 107-1, 107-2, . . . , 107-Q may include a conductive material. For example, the conductive material may include one or more of a doped semiconductor (e.g., doped silicon, doped germanium, etc.), a conductive metal nitride (e.g., titanium nitride, tantalum nitride, etc.), a metal (e.g., tungsten (W), titanium (Ti), tantalum (Ta), ruthenium (Ru), cobalt (Co), molybdenum (Mo), etc.), and/or a metal-semiconductor compound (e.g., tungsten silicide, cobalt silicide, titanium silicide, etc.). Embodiments, however, are not limited to these examples.

Among each of the vertical levels, (L1) 113-1, (L2) 113-2, and (L3) 113-P, the horizontally oriented memory cells (e.g., memory cell 110 in FIG. 1A) may be spaced apart from one another horizontally in the first direction (D1) 109. However, the plurality of discrete components to the horizontally oriented access devices 130 (e.g., first source/drain region 121 and second source/drain region 123 separated by a channel region 125), extending laterally in the second direction (D2) 105, and the plurality of horizontally oriented access lines 107-1, 107-2, . . . , 107-Q extending laterally in the first direction (D1) 109, may be formed within different vertical layers within each level. For example, the plurality of horizontally oriented access lines 107-1, 107-2, . . . , 107-Q, extending in the first direction (D1) 109, may be formed on a top surface opposing and electrically coupled to the channel regions 125, separated therefrom by a gate dielectric, and orthogonal to horizontally oriented access devices 130 extending in laterally in the second direction (D2) 105. In some embodiments, the plurality of horizontally oriented access lines 107-1, 107-2, . . . , 107-Q, extending in the first direction (D1) 109 are formed in a higher vertical layer, farther from the substrate 100, within a level (e.g., within level (L1)), than a layer in which the discrete components (e.g., first source/drain region 121 and second source/drain region 123 separated by a channel region 125), of the horizontally oriented access device are formed.

As shown in the example embodiment of FIG. 1B, the digit lines, 103-1, 103-2, . . . , 103-Q, extend in a vertical direction with respect to the substrate 100 (e.g., in a third direction (D3) 111). Further, as shown in FIG. 1B, the digit lines, 103-1, 103-2, . . . , 103-Q, in one sub cell array (e.g., sub cell array 101-2 in FIG. 1A) may be spaced apart from each other in the first direction (D1) 109. The digit lines, 103-1, 103-2, . . . , 103-Q, may be provided, extending vertically relative to the substrate 100 in the third direction (D3) 111 in vertical alignment with source/drain regions to serve as first source/drain regions 121 or, be vertically adjacent first source/drain regions 121 for each of the horizontally oriented access devices 130 extending laterally in the second direction (D2) 105, but adjacent to each other on a level (e.g., first level (L1)) in the first direction (D1) 109. Each of the digit lines, 103-1, 103-2, . . . , 103-Q, may vertically extend, in the third direction (D3), on sidewalls adjacent first source/drain regions 121 of respective ones of the plurality of horizontally oriented access devices 130 that are vertically stacked. In some embodiments, the plurality of vertically oriented digit lines 103-1, 103-2, . . . , 103-Q, extending in the third direction (D3) 111, may be connected to side surfaces of the first source/drain regions 121 directly and/or through additional contacts including metal silicides.

For example, a first one of the vertically extending digit lines (e.g., 103-1) may be adjacent a sidewall of a first source/drain region 121 to a first one of the horizontally oriented access devices 130 in the first level (L1) 113-1, a sidewall of a first source/drain region 121 of a first one of the horizontally oriented access devices 130 in the second level (L2) 113-2, and a sidewall of a first source/drain region 121 of a first one of the horizontally oriented access devices 130 in the third level (L3) 113-P, etc. Similarly, a second one of the vertically extending digit lines (e.g., 103-2) may be adjacent a sidewall to a first source/drain region 121 of a second one of the horizontally oriented access devices 130 in the first level (L1) 113-1, spaced apart from the first one of horizontally oriented access devices 130 in the first level (L1) 113-1 in the first direction (D1) 109. And the second one of the vertically extending digit lines (e.g., 103-2) may be adjacent a sidewall of a first source/drain region 121 of a second one of the laterally oriented access devices 130 in the second level (L2) 113-2, and a sidewall of a first source/drain region 121 of a second one of the horizontally oriented access devices 130 in the third level (L3) 113-P, etc. Embodiments are not limited to a particular number of levels.

The vertically extending digit lines, 103-1, 103-2, . . . , 103-Q, may include a conductive material, such as, for example, one of a doped semiconductor material, a conductive metal nitride, metal, and/or a metal-semiconductor compound. The digit lines, 103-1, 103-2, . . . , 103-Q, may correspond to digit lines (DL) described in connection with FIG. 1A.

As shown in the example embodiment of FIG. 1B, a conductive body contact 195 may be formed extending in the first direction (D1) 109 along an end surface of the horizontally oriented access devices 130 in each level (L1) 113-1, (L2) 113-2, and (L3) 113-P above the substrate 100. The body contact 195 may be connected to a body (e.g., body region) of the horizontally oriented access devices 130 in each memory cell. The body contact 195 may include a conductive material such as, for example, one of a doped semiconductor material, a conductive metal nitride, metal, and/or a metal-semiconductor compound.

Although not shown in FIG. 1B, an insulating material may fill other spaces in the vertically stacked array of memory cells. For example, the insulating material may include one or more of a silicon oxide material, a silicon nitride material, and/or a silicon oxynitride material, etc. Embodiments, however, are not limited to these examples.

FIG. 2 illustrates a portion of a horizontal access device in vertical three-dimensional (3D) memory in accordance with a number of embodiments of the present disclosure. FIG. 2 illustrates in more detail a unit cell (e.g., memory cell 110 in FIG. 1) of the vertically stacked array of memory cells (e.g., within a sub cell array 101-2 in FIG. 1) according to some embodiments of the present disclosure. As shown in FIG. 2, the first and the second source/drain regions, 221 and 223, may be impurity doped regions to the laterally oriented access devices 230. The first and the second source/drain regions 221 and 223 may be separated by a channel 225 formed in a body of semiconductor material, e.g., body region of the horizontally oriented access devices 230. The first and the second source/drain regions, 221 and 223, may be formed from an n-type or p-type dopant doped in the body region. However, embodiments are not so limited.

For example, for an n-type conductivity transistor construction the body region of the laterally oriented access devices 230 may be formed of a low doped p-type (p−) semiconductor material. In one embodiment, the body region, and the channel 225 separating the first and the second source/drain regions, 221 and 223, may include a low doped, p-type (e.g., low dopant concentration (p−)) polysilicon (Si) material consisting of boron (B) atoms as an impurity dopant to the polycrystalline silicon. The first and the second source/drain regions, 221 and 223, may also comprise a metal, and/or metal composite materials containing ruthenium (Ru), molybdenum (Mo), nickel (Ni), titanium (Ti), copper (Cu), a highly doped degenerate semiconductor material, and/or at least one of indium oxide (In₂O₃), or indium tin oxide (In2-xSnxO3), formed using an atomic layer deposition process, etc. Embodiments, however, are not limited to these examples. As used herein, a degenerate semiconductor material is intended to mean a semiconductor material, such as polysilicon, containing a high level of doping with significant interaction between dopants, e.g., phosphorus (P), boron (B), etc. Non-degenerate semiconductors, by contrast, contain moderate levels of doping, where the dopant atoms are well separated from each other in the semiconductor host lattice with negligible interaction.

In this example, the first and the second source/drain regions, 221 and 223, may include a high dopant concentration, n-type conductivity impurity (e.g., high dopant (n+)) doped in the first and the second source/drain regions, 221 and 223. In some embodiments, the high dopant, n-type conductivity first and second drain regions 221 and 223 may include a high concentration of phosphorus (P) atoms deposited therein. Embodiments, however, are not limited to this example. In other embodiments, the horizontally oriented access devices 230 may be of a p-type conductivity construction in which case the impurity (e.g., dopant) conductivity types would be reversed.

As shown in FIG. 2, the first and the second source/drain regions, 221 and 223, may be impurity doped regions to the laterally oriented access devices 230. The first and the second source/drain regions may be separated by a channel 225 formed in a body of semiconductor material (e.g., body region) of the horizontally oriented access devices 230. The first and the second source/drain regions, 221 and 223, may be formed from an n-type or p-type dopant doped in the body region. However, embodiments are not so limited.

The first source/drain region 221 may occupy an upper portion in the body of the laterally oriented access devices 230. For example, the first source/drain region 221 may have a bottom surface within the body of the horizontally oriented access device 230 which is located higher, vertically in the third direction (D3) 211, than a bottom surface of the body of the laterally, horizontally oriented access device 230. As such, the laterally, horizontally oriented transistor 230 may have a body portion which is below the first source/drain region 221 and is in electrical contact with the body contact. Further, as shown in the example embodiment of FIG. 2, an access line (e.g., 207) analogous to the access lines 107-1, 107-2, . . . , 107-Q shown in FIG. 1, may disposed on a top surface opposing and coupled to a channel region 225, separated therefrom by a gate dielectric 204. The gate dielectric material 204 may include, for example, a high-k dielectric material, a silicon oxide material, a silicon nitride material, a silicon oxynitride material, etc., or a combination thereof. Embodiments are not so limited. For example, in high-k dielectric material examples the gate dielectric material 204 may include one or more of hafnium oxide, hafnium silicon oxide, lanthanum oxide, zirconium oxide, zirconium silicon oxide, tantalum oxide, titanium oxide, barium strontium titanium oxide, barium titanium oxide, strontium titanium oxide, lithium oxide, aluminum oxide, lead scandium tantalum oxide, lead zinc niobite, etc.

As shown in the example embodiment of FIG. 2, a digit line (e.g., 203-1) analogous to the digit lines 103-1, 103-2, . . . , 103-Q in FIG. 1, may be vertically extending in the third direction (D3) 211 adjacent a sidewall of the first source/drain region 221 in the body to the horizontally oriented access devices 230 horizontally conducting between the first and the second source/drain regions 221 and 223 along the second direction (D2) 205. In this embodiment, the vertically oriented digit line 203-1 is formed symmetrically, in vertical alignment, and in electrical contact with the first source/drain region 221. The digit line 203-1 may be formed in contact with an insulator material such that there is no body contact within channel 225.

As shown in the example embodiment of FIG. 2, the digit line 203-1 may be formed symmetrically within the first source/drain region 221 such that the first source/drain region 221 surrounds the digit line 203-1 all around. The first source/drain region 221 may occupy an upper portion in the body of the laterally oriented access devices 230. For example, the first source/drain region 221 may have a bottom surface within the body of the horizontally oriented access device 230 which is located higher, vertically in the third direction (D3) 211, than a bottom surface of the body of the laterally, horizontally oriented access device 230. As such, the laterally, horizontally oriented access device 230 may have a body portion which is below the first source/drain region 321 and is in contact with the body contact. An insulator material may fill the body contact such that the first source/drain region 221 may not be in electrical contact with channel 225. Further, as shown in the example embodiment of FIG. 2, an access line 207 analogous to the access lines 107-1, 107-2, . . . , 107-Q shown in FIG. 1, may be disposed all around and coupled to a channel region 225, separated therefrom by a gate dielectric 204.

Although the digit line 203-1 is described above as being formed symmetrically within the first source/drain region 221 such that the first source/drain region 221 surrounds the digit line 203-1 all around, embodiments are not so limited. For instance, in some examples, the digit line 203-1 can be formed asymmetrically. In this embodiment, the vertically oriented digit line is formed asymmetrically adjacent in electrical contact with the first source/drain regions 221. The digit line may be formed asymmetrically to reserve room for a body contact in the channel region 225.

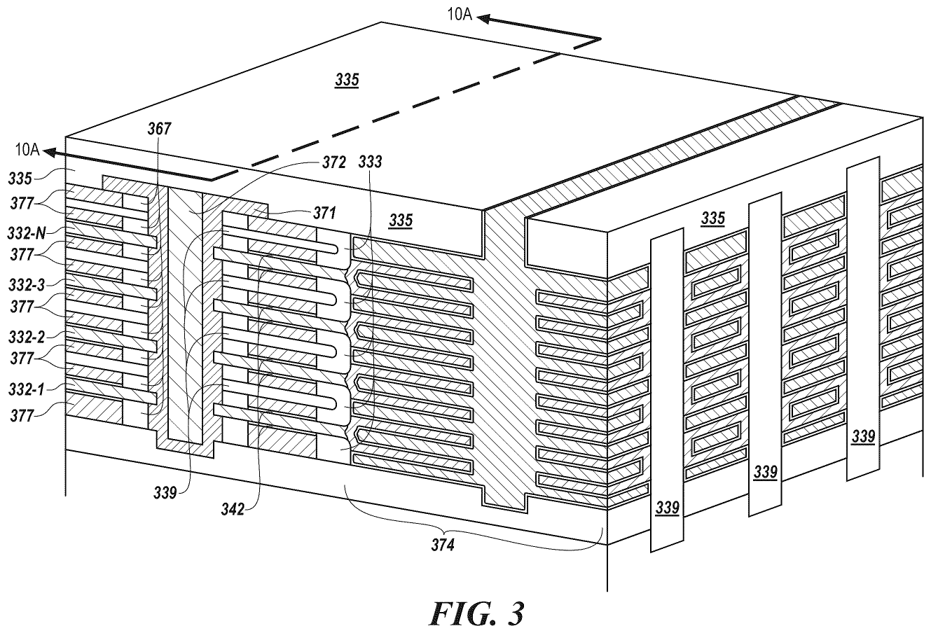

FIG. 3 is a perspective view illustrating horizontal access devices in accordance with a number of embodiments of the present disclosure. FIG. 3 includes first conductive material 377, a silicon (Si) material 332, a photolithographic mask material (e.g., mask material) 335, a third dielectric material 367, a second conductive material 370, a metal material 372, a first dielectric material 339, a second dielectric material 333, a second interlayer dielectric material 342, and a plurality of storage nodes (e.g., capacitors) 374.

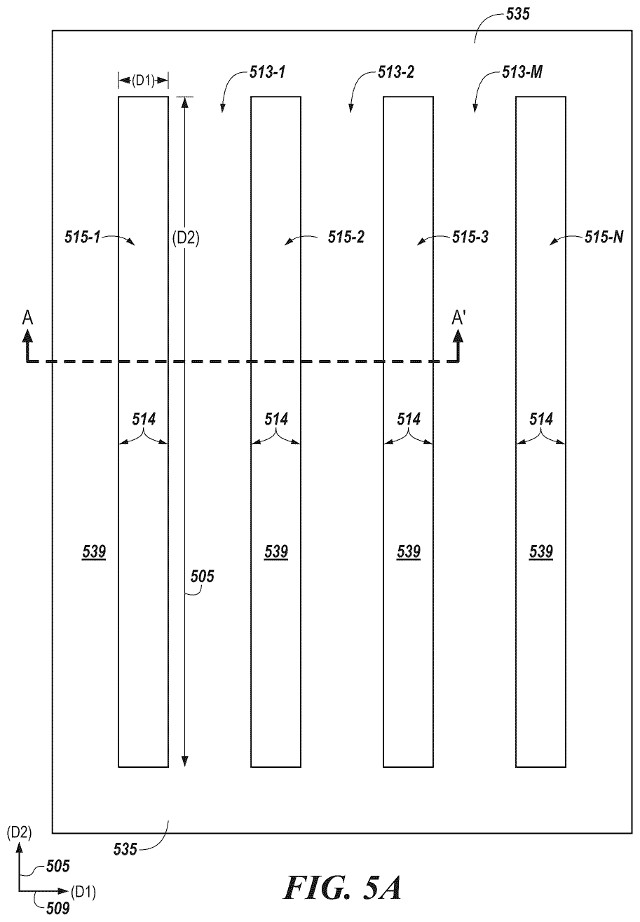

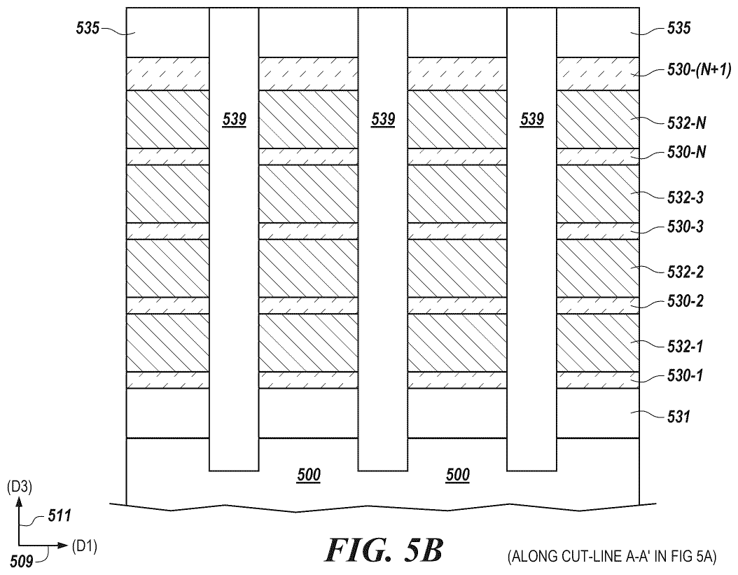

FIG. 3 illustrates a portion of a vertical 3D memory array that is formed in accordance with the process described in FIGS. 5-9 of this application. The horizontal access devices of the vertical 3D memory array can include the second dielectric material 333, the first conductive material 377, a first dielectric material 339, and third dielectric material 367. In some embodiments, the first dielectric material 339 can be formed using an oxide material. Further, in some embodiments, the first dielectric material 339 and the second dielectric material 333 can be formed from the same material. In other embodiments, a first material can be used to form the first dielectric material 339 and a second material can be used to form the second dielectric material 333, wherein the first material is a different material than the second material.

The access devices can be coupled to the plurality of storage nodes 374. In some embodiments, the plurality of storage nodes 374 can be double-sided capacitors. The access devices can be used to transfer current between the metal material 372 and the plurality of storage nodes 374, which is a stack of multiple storage nodes, such as a stack of storage nodes 227 in FIG. 2.

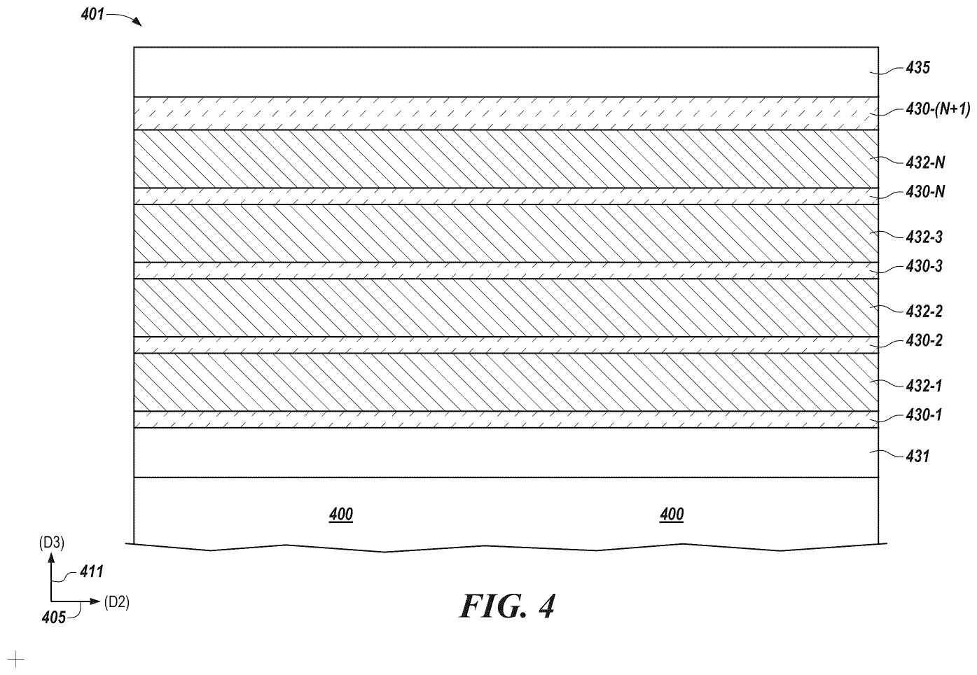

FIG. 4 is a cross-sectional view of a vertical stack in vertical three dimensional (3D) memory in accordance with a number of embodiments of the present disclosure. In the example embodiment shown in the example of FIG. 4, a method of forming the vertical stack 401 can comprise forming alternating layers of a silicon germanium (SiGe) material, 430-1, 430-2, . . . , 430-N (collectively referred to as silicon germanium (SiGe) 430), and a silicon (Si) material, 432-1, 432-2, . . . , 432-N (collectively referred to as single crystalline silicon (Si) material 432), in repeating iterations to form a vertical stack 401 on a working surface of a semiconductor substrate 400. In some embodiments, the silicon germanium (SiGe) material and the silicon (Si) material can be epitaxially grown.

In one embodiment, the silicon germanium (SiGe) 430 can be deposited to have a thickness (e.g., vertical height) in the third direction (D3), in a range of five (5) nanometers to thirty (30) nm. In one embodiment, the silicon (Si) material 432 can be deposited to have a thickness in a range of thirty (30) nanometers (nm) to sixty (60) nm. Embodiments, however, are not limited to these examples. As shown in FIG. 4, a vertical direction 411 is illustrated as a third direction (D3) (e.g., z-direction in an x-y-z coordinate system) analogous to the third direction (D3), among first, second, and third directions, shown in FIGS. 1-3.

In some embodiments, the silicon germanium (SiGe), 430-1, 430-2, . . . , 430-N, may be a mix of silicon and germanium. By way of example, and not by way of limitation, the silicon germanium (SiGe) material 430 may be grown on the substrate material 400. Embodiments are not limited to these examples. In some embodiments, the single crystalline silicon (Si) material, 432-1, 432-2, . . . , 432-N, may comprise a silicon (Si) material in a polycrystalline and/or amorphous state. The single crystalline silicon (Si) material, 432-1, 432-2, . . . , 432-N, may be a low doped, p-type (p−) single crystalline silicon (Si) material. The silicon (Si) material, 432-1, 432-2, . . . , 432-N, may also be formed on the silicon germanium (SiGe) 430. If the silicon germanium (SiGe) 430 was epitaxially grown, the seed can be turned to pure silicon after the silicon germanium (SiGe) 430 has been formed.

The repeating iterations of alternating silicon germanium (SiGe), 430-1, 430-2, . . . , 430-N layers and single crystalline silicon (Si) material, 432-1, 432-2, . . . , 432-N layers may be deposited according to a semiconductor fabrication process such as chemical vapor deposition (CVD) in a semiconductor fabrication apparatus. Embodiments, however, are not limited to this example and other suitable semiconductor fabrication techniques may be used to deposit the alternating layers of silicon germanium (SiGe) and single crystalline silicon (Si) material, in repeating iterations to define the vertical stack 401.

The layers may occur in repeating iterations vertically. For example, the stack may include: a first silicon germanium (SiGe) material 430-1, a first single crystalline silicon (Si) material 432-1, a second silicon germanium (SiGe) material 430-2, a second single crystalline silicon (Si) material 432-2, a third silicon germanium (SiGe) material 430-3, and a third single crystalline silicon (Si) material 432-3, in further repeating iterations. Embodiments, however, are not limited to this example and more or fewer repeating iterations may be included.

In some embodiments, a bottom portion of the vertical stack 401 can be removed to form a horizontal opening. The bottom portion of the vertical stack 401 can include a layer of silicon germanium (SiGe) material 430 that is closer to the substrate 400 than other layers of silicon germanium (SiGe) material 430, a layer of silicon (Si) material 432 that is closer to the substrate 400 than other layers of silicon (Si) material 432, or both. Further, a dielectric material 431 can be deposited to fill the horizontal opening.

FIG. 5A illustrates an example method, at one stage of a semiconductor fabrication process, for forming a partition outside of a 3D memory array for a memory device, in accordance with a number of embodiments of the present disclosure. FIG. 5A illustrates a top down view of a semiconductor structure, at a particular point in time, in a semiconductor fabrication process, according to one or more embodiments. In the example embodiment shown in the example of FIG. 5A, the method comprises using an etchant process to form a plurality of vertical openings 515-1, 515-2, 515-3, . . . , 515-N (individually or collectively referred to as vertical openings 515), having a first horizontal direction (D1) 509 and a second horizontal direction (D2) 505, through the vertical stack to the substrate. In one example, as shown in FIG. 5A, the plurality of vertical openings 515 are extending predominantly in the second horizontal direction (D2) 505 and may define elongated vertical columns of the alternating layers 513-1, 513-2, . . . , 513-M (collectively and/or independently referred to as vertical, pillar columns 513), with sidewalls 514 in the vertical stack. The plurality of first vertical openings 515 may be formed using photolithographic techniques to pattern a photolithographic mask 535 (e.g., to form a hard mask (HM)), on the vertical stack prior to etching the plurality of first vertical openings 515. Similar semiconductor process techniques may be used at other points of the semiconductor fabrication process described herein.

The first vertical openings 515 may be filled with a first dielectric material 539. In one example, a spin on dielectric process may be used to fill the first vertical openings 515. In one embodiment, the first dielectric material 539 may be an oxide material. However, embodiments are not so limited.

FIG. 5B is a cross sectional view, taken along cut-line A-A′ in FIG. 5A, showing another view of the semiconductor structure at a particular time in the semiconductor fabrication process for forming a partition outside of a 3D memory array for a memory device, in accordance with a number of embodiments of the present disclosure. The cross sectional view shown in FIG. 5B shows the repeating iterations of alternating layers of a silicon germanium (SiGe) material 530 and a single crystalline silicon (Si) material 532 on a semiconductor substrate 500 to define the vertical stack (e.g., vertical stack 501 in FIG. 5).

As shown in FIG. 5B, a plurality of vertical openings may be formed through the layers within the vertically stacked memory cells to expose vertical sidewalls in the vertical stack and define elongated vertical pillar columns (e.g., vertical pillar columns 513 in FIG. 5A) and then filled with a first dielectric material 539. The first vertical openings (e.g., first vertical openings 515 in FIG. 5A) may be formed through the repeating iterations of the silicon germanium (SiGe) material 530 and the single crystalline silicon (Si) material 532. As such, the first vertical openings may be formed through a first silicon germanium (SiGe) material 530-1, a first single crystalline silicon (Si) material 532-1, a second silicon germanium (SiGe) material 530-2, a second single crystalline silicon (Si) material 532-2, a third silicon germanium (SiGe) material 530-3, and a third single crystalline silicon (Si) material 532-3. Embodiments, however, are not limited to the vertical opening(s) shown in FIG. 5B. Multiple vertical openings may be formed through the layers of materials. The vertical openings may be formed to expose vertical sidewalls in the vertical stack. The vertical openings may extend in a second direction (D2) 505 to define elongated vertical columns of the alternating layers with vertical sidewalls in the vertical stack and then filled with first dielectric 539.

As shown in FIG. 5B, a first dielectric material 539, such as an oxide or other suitable spin on dielectric (SOD), may be deposited in the first vertical openings, using a process such as CVD, to fill the first vertical openings. First dielectric material 539 may also be formed from a nitride (N) material. In one example, the N material can be a silicon nitride (Si₃N₄) material. In another example, the first dielectric material 539 may include silicon oxy-nitride (SiOₓN_{y}), and/or combinations thereof. Embodiments are not limited to these examples. The plurality of first vertical openings may be formed using photolithographic techniques to pattern a photolithographic mask 535 (e.g., to form a hard mask (HM)) on the vertical stack prior to etching the plurality of first vertical openings. In one embodiment, hard mask 535 may be deposited over a silicon germanium (SiGe) material 530. Similar semiconductor process techniques may be used at other points of the semiconductor fabrication process described herein.

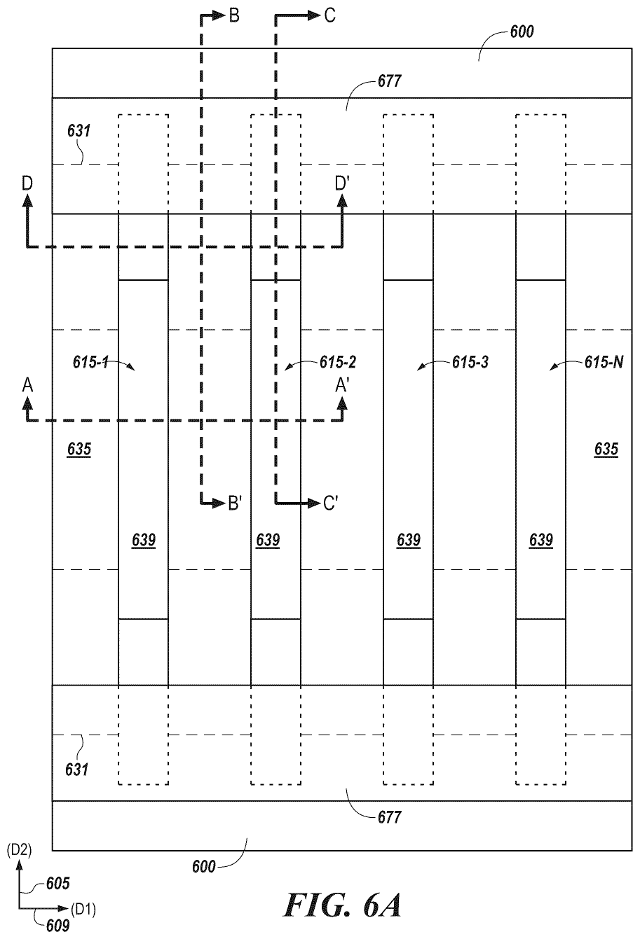

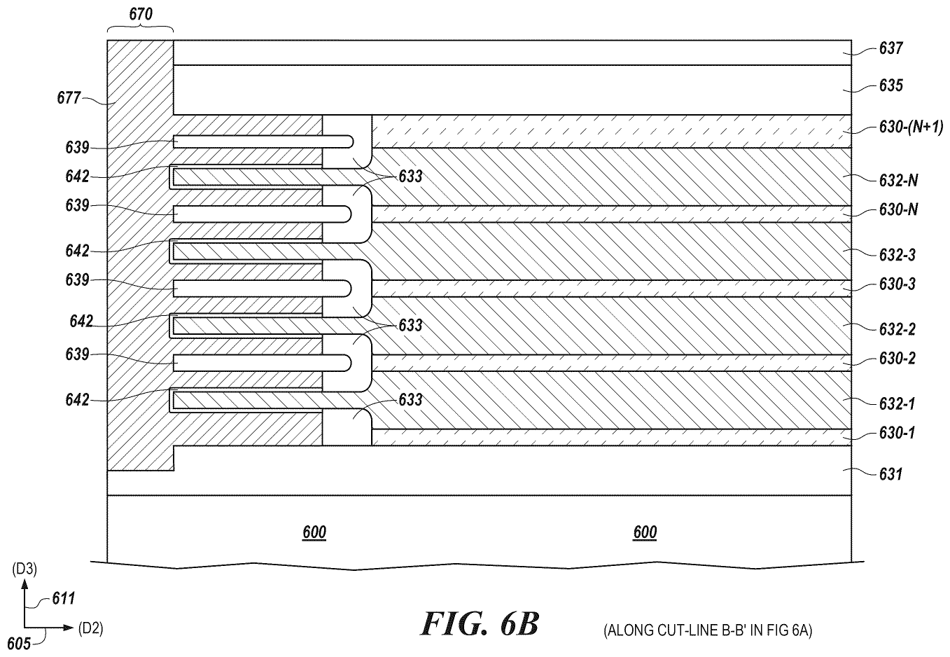

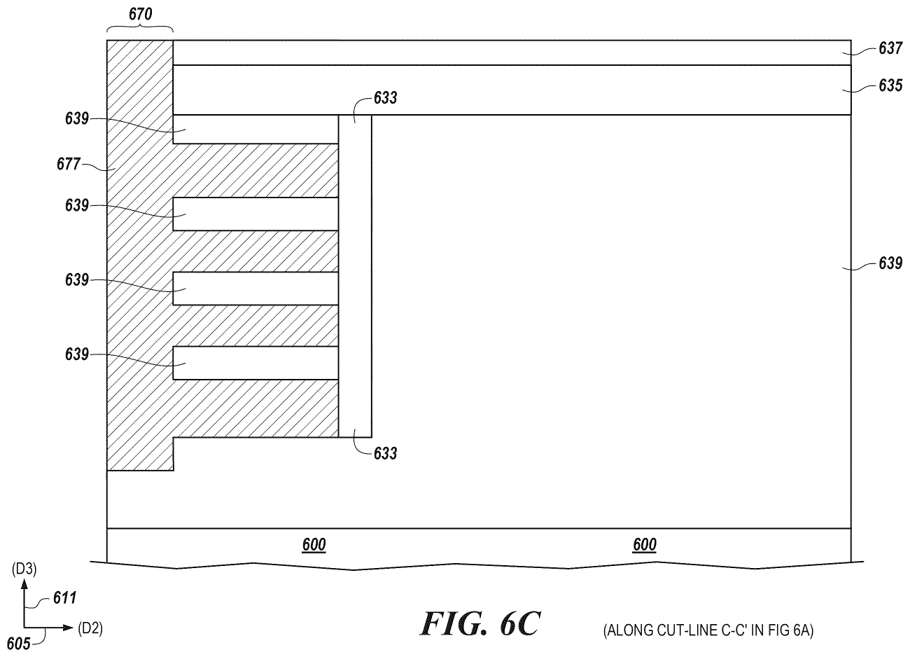

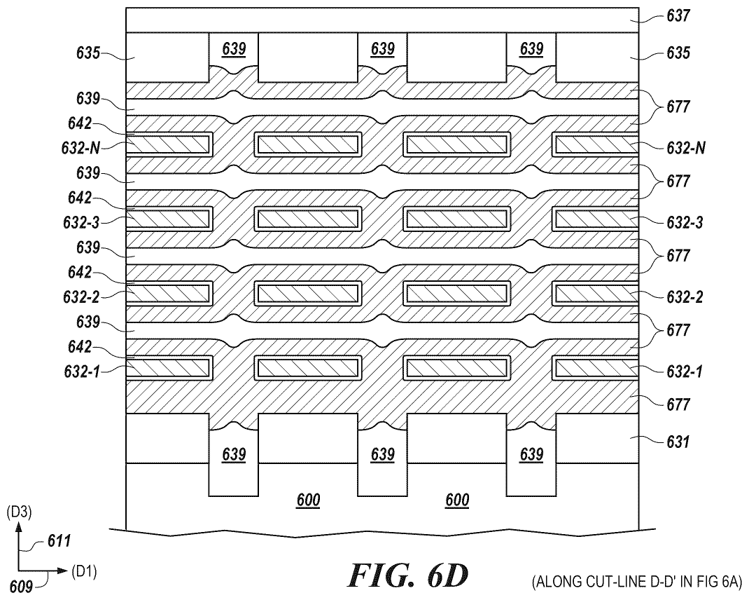

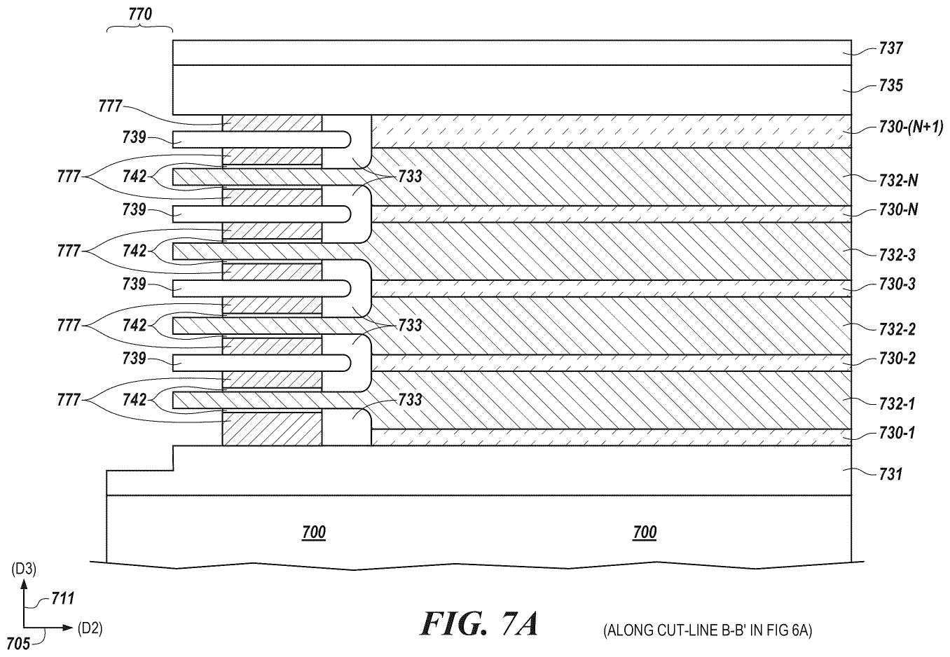

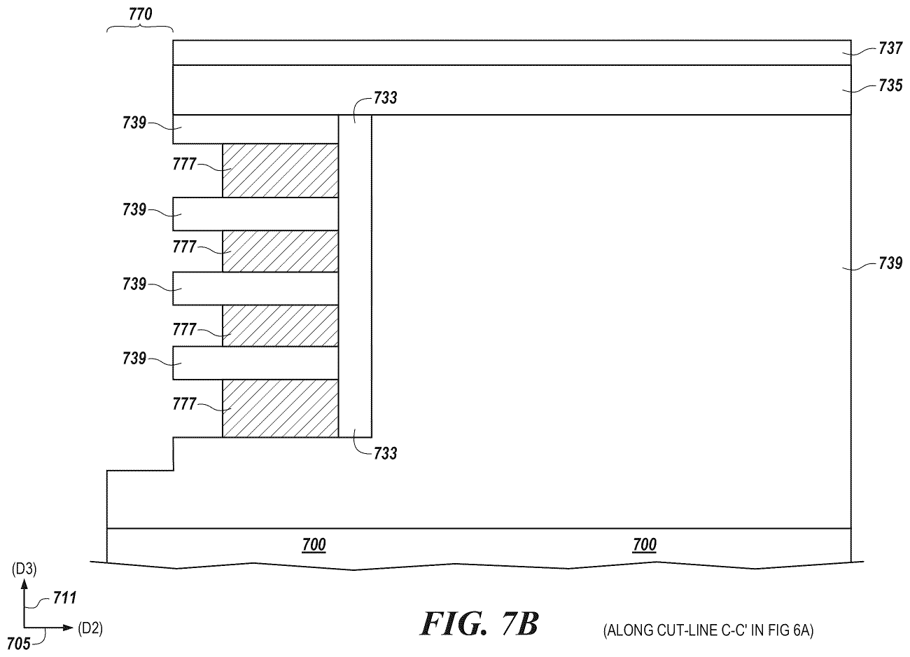

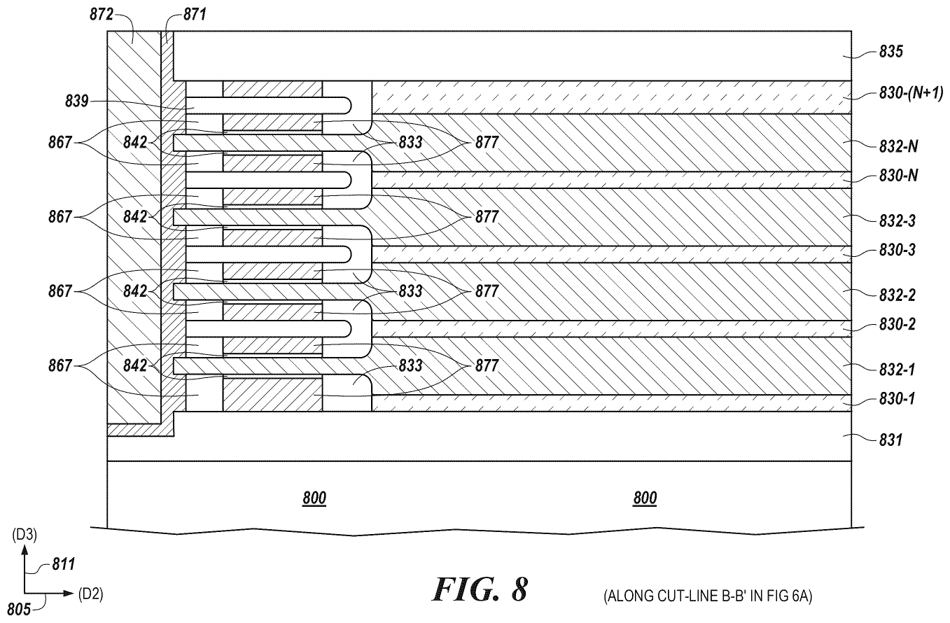

FIG. 6A illustrates an example method, at another stage of a semiconductor fabrication process for forming a partition outside of a 3D memory array for a memory device, in accordance with a number of embodiments of the present disclosure. FIG. 6A illustrates a top down view of a semiconductor structure, at a particular point in time, in a semiconductor fabrication process, according to one or more embodiments. In the example embodiment of FIG. 6A, the method comprises using a photolithographic process to pattern the photolithographic mask 635. A first conductive material 677 may be deposited above the vertical openings 631. The first conductive material 677 may be deposited in the continuous first horizontal openings to form horizontally oriented access lines opposing channel regions of the single crystalline silicon (Si) material 632.

FIG. 6B illustrates a cross sectional view, taken along cut-line B-B′ in FIG. 6A, showing another view of the semiconductor structure at this particular point in one example semiconductor fabrication process for forming a partition outside of a 3D memory array for a memory device, in accordance with embodiments of the present disclosure. The cross sectional view shown in FIG. 6B is illustrated extending in the second horizontal direction (D2) 605, left and right along the plane of the drawing sheet, along an axis of the repeating iterations of alternating layers of the silicon germanium (SiGe) material 630 and the single crystalline silicon (Si) material 632.

A process of depositing and etching materials can be used to form the structure shown in FIG. 6B. In some embodiments, the process of depositing and etching materials can include forming horizontally oriented access devices and horizontally oriented storage nodes (e.g., storage nodes 227 in FIG. 2) at each level of the vertical stack (e.g., vertical stack 401 in FIG. 4) to form an array of vertically stacked memory cells. Each of the horizontally oriented access devices can have first source/drain regions and second source/drain regions separated by channel regions. In some embodiments, gates can be formed fully around every surface of the channel regions as gate all around (GAA) structures on a gate dielectric material. Further, in some embodiments, the second source/drain regions can be coupled to storage nodes.

The semiconductor structure shown in FIG. 6B shows the semiconductor structure after the silicon germanium (SiGe) layers are selectively etched to form a plurality of first horizontal openings a first length from first vertical openings 670. In some embodiments, the second vertical openings 670 can be formed to a depth in a range of 0.5 to one (1) micrometer (μm). Further, in some embodiments, each of the first vertical openings 670 can be formed to have an aspect ratio in a range of 15-20. In some embodiments, the selective etch that forms the plurality of first horizontal openings can also reduce a vertical thickness of the silicon (Si) layers. In some embodiments, a vertical thickness of a portion of each of the silicon (Si) layers can be reduced to a vertical thickness in a range of 100-150 Angstroms (Å).

The process of forming the horizontally oriented access devices can further include conformally depositing a second dielectric material 633 on exposed surfaces in the plurality of first horizontal openings and depositing the first dielectric material 639 to fill the plurality of first horizontal openings. The second dielectric material 633 can be selectively etched from the plurality of first horizontal openings a second length (L2) from the first vertical opening 670. In some embodiments, the second length (L2) can be a length in a range of 130-170 nanometers (nm).

A first conductive material 677 may be deposited in the first horizontal opening on the gate dielectric material 642 after selectively etching the first dielectric material 639. The first conductive material 677 may be deposited around the single crystalline silicon (Si) material 632 such that the first conductive material 677 may have a top portion above the single crystalline silicon (Si) material 632 and a bottom portion below the single crystalline silicon (Si) material to form a gate all around (GAA) gate structure, at a channel of an access device region. The first conductive material 677 may be conformally deposited into vertical openings 670 and fill the continuous horizontal openings up to the unetched portions of the gate dielectric material 642, the first dielectric material 639, and the second dielectric material 633. The conductive material 677 may be conformally deposited using a chemical vapor deposition (CVD) process, plasma enhanced CVD (PECVD), atomic layer deposition (ALD), or other suitable deposition process.

In some embodiments, the first conductive material, 677, may comprise one or more of a doped semiconductor (e.g., doped silicon, doped germanium, etc.), a conductive metal nitride (e.g., titanium nitride, tantalum nitride, etc.), a metal (e.g., tungsten (W), titanium (Ti), tantalum (Ta), ruthenium (Ru), cobalt (Co), molybdenum (Mo), etc.), and/or a metal-semiconductor compound (e.g., tungsten silicide, cobalt silicide, titanium silicide, etc.), and/or some other combination thereof. The first conductive material 677 entwined with the gate dielectric material may form horizontally oriented access lines opposing a channel region of the single crystalline silicon (Si) material (which also may be referred to as word lines).

FIG. 6C illustrates a cross sectional view, taken along cut-line C-C′ in FIG. 6A, showing another view of the semiconductor structure at this particular point in one example semiconductor fabrication process for forming a partition outside of a 3D memory array for a memory device, in accordance with embodiments of the present disclosure. The cross sectional view shown in FIG. 6C is illustrated extending in the second horizontal direction (D2) 605, left and right in the plane of the drawing sheet, along an axis of the repeating iterations of alternating layers of continuous horizontal openings and single crystalline silicon (Si) material (e.g., silicon (Si) material 632 in FIG. 6B).

In FIG. 6C, first dielectric material 639 is shown spaced along a second horizontal direction (D2) 605, extending into and out from the plane of the drawings sheet, for a three dimensional (3D) array of vertically oriented memory cells. At the left end of the drawing sheet is shown the repeating iterations of alternating layers of first dielectric material 639, separated by continuous horizontal openings in a first direction (D1) 609 filled with a first conductive material 677. The first conductive material 677 may be conformally deposited into vertical openings 670 and into the horizontal openings. The first conductive material 677 can be formed on the gate dielectric material (e.g., gate dielectric material 642 in FIG. 6B). At the right hand of the drawing sheet, the first dielectric material 639 may be seen, separating access device and storage node regions in the first direction (D1) 609, and having the horizontal opening filled with the second dielectric material 633 and the first dielectric material 639.

FIG. 6D illustrates a cross sectional view, taken along cut-line D-D′ in FIG. 6A, showing another view of the semiconductor structure at this particular point in one example semiconductor fabrication process for forming a partition outside of a 3D memory array in a memory device, in accordance with a number of embodiments of the present disclosure. The cross sectional view shown in FIG. 6D is illustrated, right to left in the plane of the drawing sheet, extending in the first direction (D1) 609 along an axis of the repeating iterations of alternating layers of first dielectric material 639 and single crystalline silicon (Si) material 632 wrapped with a gate dielectric material 642. The gate dielectric material 642 may be conformally deposited fully around every surface of the single crystalline silicon (Si) material 632, to form gate all around (GAA) gate structures, at the channels of the access device regions. The first conductive material 677 may fill the spaces adjacent the bridged single crystalline silicon (Si) material 632. The single crystalline silicon (Si) material 632 may be surrounded by the first conductive material 677 formed on the gate dielectric material 642. The first conductive material 677 may be conformally deposited fully around every surface of the single crystalline silicon (Si) material 632, to form gate all around (GAA) gate structures, at the channels of the access device regions. In FIG. 6D, the first conductive material, 677 is shown filling in the space in the second horizontal openings left by the etched second dielectric material 633.

FIG. 7A illustrates an example method, at another stage of a semiconductor fabrication process, for forming a partition outside of a 3D memory array for a memory device, in accordance with a number of embodiments of the present disclosure. The cross sectional view shown in FIG. 7A is illustrated extending in the second horizontal direction (D2) 705, left and right along the plane of the drawing sheet, along an axis of the repeating iterations of alternating layers of the silicon germanium (SiGe) material 730 and the single crystalline silicon (Si) material 732.

A first conductive material 777 was deposited on the gate dielectric material and formed around the single crystalline silicon (Si) material 732, recessed back, to form a gate all around (GAA) structure opposing channel regions of the single crystalline silicon (Si) material 732. The first conductive material 777, formed on the gate dielectric material 742, may be recessed and etched away from the vertical opening 770. In some embodiments, the first conductive material 777 may be etched using an atomic layer etching (ALE) process. In some embodiments, the first conductive material 777 may be etched using an isotropic etch process. The first conductive material 777 may be selectively etched leaving the oxide material 742 covering the single crystalline silicon (Si) material 732 and the first dielectric material 739 intact. The first conductive material 777 may be selectively etched in the second direction, in the continuous horizontal openings, a third distance in a range of twenty (20) to fifty (50) nanometers (nm) back from the first vertical opening 770. The first conductive material 777 may be selectively etched around the single crystalline silicon (Si) material 732 back into the continuous horizontal openings extending in the first horizontal direction.

FIG. 7B illustrates an example method, at another stage of a semiconductor fabrication process, for forming a partition outside of a 3D memory array in a memory device, in accordance with a number of embodiments of the present disclosure. The cross sectional view shown in FIG. 7B is illustrated extending in the second direction (D2) 705, left and right in the plane of the drawing sheet, along an axis of the repeating iterations of alternating layers of the etched first conductive material 777 and single crystalline silicon (Si) material 732.

In FIG. 7B, first dielectric material 739 is shown spaced along a first horizontal direction (D1) 709 extending into and out from the plane of the drawings sheet, for a three dimensional (3D) array of vertically oriented memory cells. At the left end of the drawing sheet is shown the first conductive material 777 formed on the gate dielectric material 742, was etched away from the vertical opening 770. The first conductive material 777, formed on the gate dielectric material 742, is also recessed back in the continuous horizontal openings extending in the first horizontal direction 709. The first conductive material 777 may be selectively etched leaving the oxide material 742 covering the single crystalline silicon (Si) material 732 intact. In some embodiments, the first conductive material 777 may be etched using an atomic layer etching (ALE) process. In some embodiments, the first conductive material 777 may be etched using an isotropic etch process.

FIG. 8 illustrates an example method, at another stage of a semiconductor fabrication process, for forming a partition outside of a 3D memory array in memory device, in accordance with a number of embodiments of the present disclosure. The cross sectional view shown in FIG. 8 is illustrated extending in the second horizontal direction (D2) 805, left and right along the plane of the drawing sheet.

FIG. 8 illustrates an example embodiment of a vertical digit line formed by the combination of second conductive material 871 and third conductive material 872 formed within the first vertical openings (e.g., vertical openings 770 in FIG. 7). In some embodiments, the third conductive material can be formed by flowing a conductive material (e.g., a tungsten hexafluoride material) over exposed surfaces of the second conductive material 871 to form bi-layer vertical sense lines in the array region. The bi-layer vertical sense lines can each include an outer layer of tungsten and an inner layer of doped Si material. In one example, a second conductive material 871 may be conformally formed in the vertical openings. The second conductive material 871 may be formed from a conformal deposition of a highly doped polysilicon material. In one example, the dopant can include a high concentration n-type dopant. In a further example, the polysilicon may first be deposited and then a high concentration of n-type dopant may be implanted therein from the second conductive material 871. One example of forming the second conductive material 870 includes conformally depositing a highly phosphorus (P) doped (n+-type dopant) poly-silicon germanium (SiGe) material into the first vertical openings for the second conductive material 871.

A third conductive material 872 may be deposited into the first vertical opening on the second conductive material 871 to fill the vertical opening as shown in FIG. 8. In some embodiments, the third conductive material 872 may comprise one or more of a doped semiconductor material, e.g., doped silicon, doped germanium, etc., a conductive metal nitride, e.g., titanium nitride, tantalum nitride, etc., a metal, e.g., tungsten (W), titanium (Ti), tantalum (Ta), ruthenium (Ru), cobalt (Co), molybdenum (Mo), etc., and/or a metal-semiconductor compound, e.g., tungsten silicide, cobalt silicide, titanium silicide, etc., and/or some other combination thereof. The third conductive material 872 coupled to the second conductive material 871 may be formed vertically adjacent first source/drain regions to horizontal access devices to form vertical digit lines.

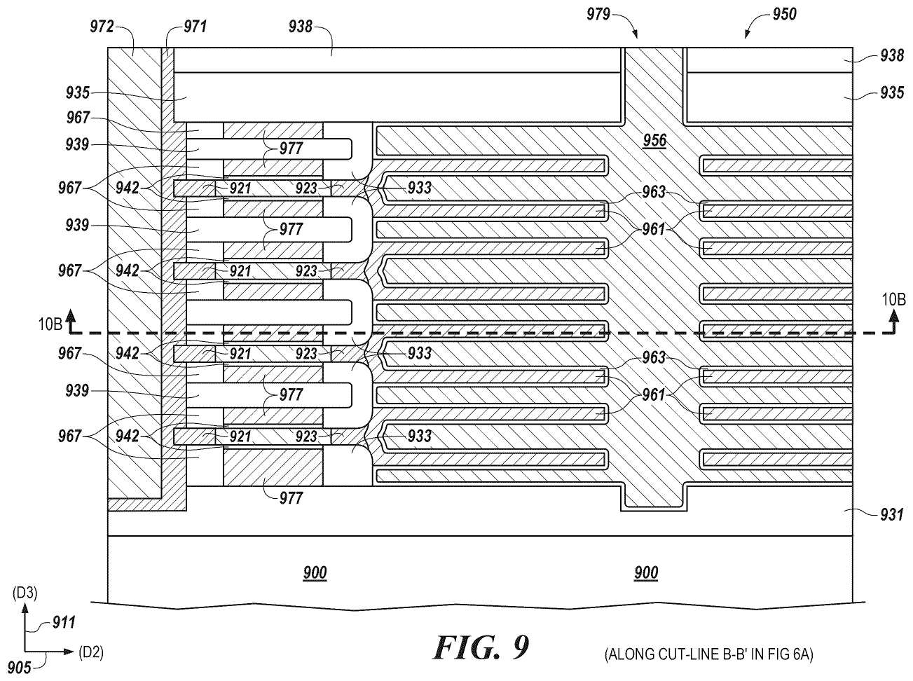

FIG. 9 illustrates an example method at another stage of a semiconductor fabrication process for forming a partition outside of a 3D memory array for a memory device, in accordance with a number of embodiments of the present disclosure. The cross sectional view shown in FIG. 9 is illustrated extending in the second horizontal direction (D2) 905, left and right along the plane of the drawing sheet, along the axis of repeating iterations of alternating layers of second electrodes 956 in which the horizontally oriented access devices and horizontally oriented storage nodes, e.g., capacitor cells, can be formed within the layers of silicon (Si) material.

In the example embodiment of FIG. 9, the horizontally oriented storage nodes (e.g., capacitor cells) are illustrated as having been formed in this semiconductor fabrication process and first electrodes 961 (e.g., bottom electrodes) to be coupled to source/drain regions of horizontal access devices, and second electrodes 956 (e.g., top electrodes) to be coupled to a common electrode plane such as a ground plane, separated by cell dielectrics 963, are shown. In this embodiment, a dual-sided capacitor is illustrated as an alternative to the single-sided capacitor. However, embodiments are not limited to this example. In other embodiments, the first electrodes 961 (e.g., bottom electrodes) to be coupled to source/drain regions of horizontal access devices, and second electrodes 956 (e.g., top electrodes) to be coupled to a common electrode plane such as a ground plane, separated by cell dielectrics 963, may be formed subsequent to forming a first source/drain region 921, a channel region, and a second source/drain region 923 in a region of the epitaxially grown, single crystalline silicon (Si) material 932, intended for location (e.g., placement formation) of the horizontally oriented access devices.

In the example embodiment of FIG. 9, the horizontally oriented storage nodes having the first electrodes 961 (e.g., bottom electrodes) to be coupled to source/drain regions of horizontal access devices, and second electrodes 956 (e.g., top electrodes) to be coupled to a common electrode plane such as a ground plane, are shown formed in a horizontal opening, extending in second direction 905, left and right in the plane of the drawing sheet, a distance from the vertical opening formed in the vertical stack, and along an axis of orientation of the horizontal access devices and horizontal storage nodes of the arrays of vertically stacked memory cells of the three dimensional (3D) memory.

In FIG. 9, a neighboring, horizontal access line 977 is illustrated adjacent the second dielectric material 933, with a portion of the first conductive material 977 located above the silicon (Si) material 932, and a portion of the first conductive material 977 located below the silicon (Si) material 932 indicating a location set inward from the plane and orientation of the drawing sheet. The first source/drain regions 921 and the second source/drain regions 923 may be formed by gas phase doping a dopant in a side surface of the silicon (Si) material 932 from the horizontal openings to form second source/drain regions 923 horizontally adjacent the channel region; and depositing horizontally oriented capacitor cells having a bottom electrode formed in electrical contact with the second source/drain regions 923.

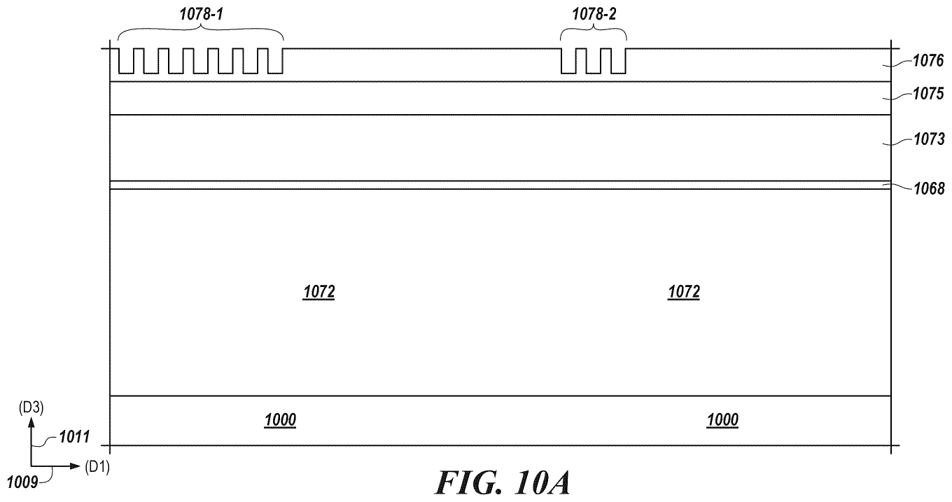

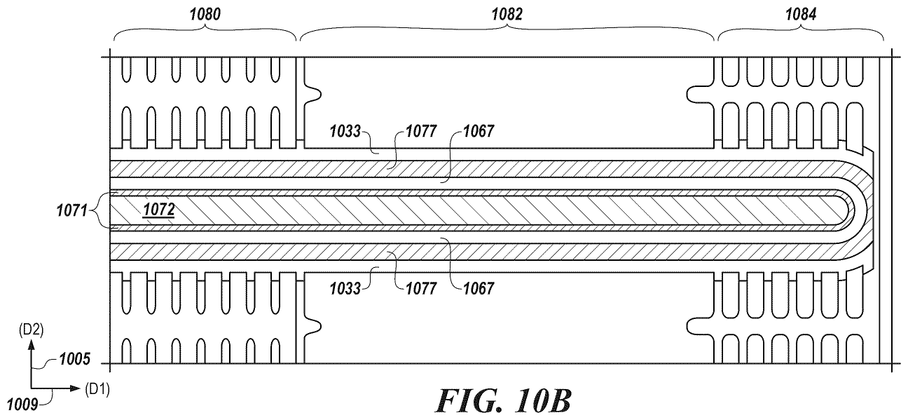

FIG. 10A illustrates an example method at another stage of a semiconductor fabrication process for forming a partition outside of a 3D memory array for a memory device, in accordance with a number of embodiments of the present disclosure. The cross sectional view shown in FIG. 10A, e.g. cross sectional view taken along cut-line 10A-10A in FIG. 3, is illustrated extending in the first horizontal direction (D1) 1009, left and right along the plane of the drawing sheet, along the axis of the third conductive material 1072, e.g., a conductive material for sense line (digit line (DL)) formation. FIG. 10A also illustrates a substrate 1000 on which the structure of semiconductor fabrication process is formed. In the cross sectional view of FIG. 10A is illustrated a first sacrificial material 1073 formed over the third conductive material 1072, a second sacrificial material 1075 formed over the first sacrificial material 1073, and a first mask material 1076 formed over the second sacrificial material 1075.

As shown in FIG. 10A, the first mask material 1076 can be patterned in the array region and the patch isolation region. In some embodiments, the first mask material 1076 can be patterned in the array region and the patch isolation region concurrently. The array region patterning 1078-1 can form a first number of slots and the patch isolation region patterning 1078-2 can form a second number of slots. In some embodiments, as shown in FIG. 10A, the first number of slots can be a different number of slots than the second number of slots.

FIG. 10B illustrates a cross sectional, top down view, e.g., taken along cut-line 10B-10B in FIG. 9, of an example method at the stage illustrated in FIG. 10A of a semiconductor fabrication process for forming a partition outside of a 3D memory array for a memory device, in accordance with a number of embodiments of the present disclosure. The embodiment illustrated in FIG. 10B may be illustrative of the structure before storage nodes, e.g., capacitors, for the memory cells have been formed. The cross sectional view of FIG. 10B illustrates a second dielectric material 1033, e.g., nitride material, of a horizontally oriented access device, a first conductive material 1077, e.g. conductive material for an access line (e.g., word line (WL)), of a horizontally oriented access device, and a third dielectric material 1067, which may be the same or different from the second dielectric material 1033, of a horizontally oriented access device. Further, 10B illustrates a second conductive material 1071 of a vertically oriented sense line and a third conductive material 1072 of the vertically oriented sense line, e.g., multi-layer digit line (DL). In some embodiments, the third conductive material 1072 can be a doped Si material and the second conductive material 1071 can be a titanium nitride (TiN) material. Embodiments, however, are not limited to these examples.

FIG. 10B further illustrates an array region 1080, a patch isolation region 1082, and another array region 1084. In some embodiments, as shown in FIG. 10B, the patch isolation region 1082 can be located between the array region 1080 and the array region 1084 in a first horizontal direction (D1) and provide separation and/or isolation between the array region 1080 and the array region 1084.

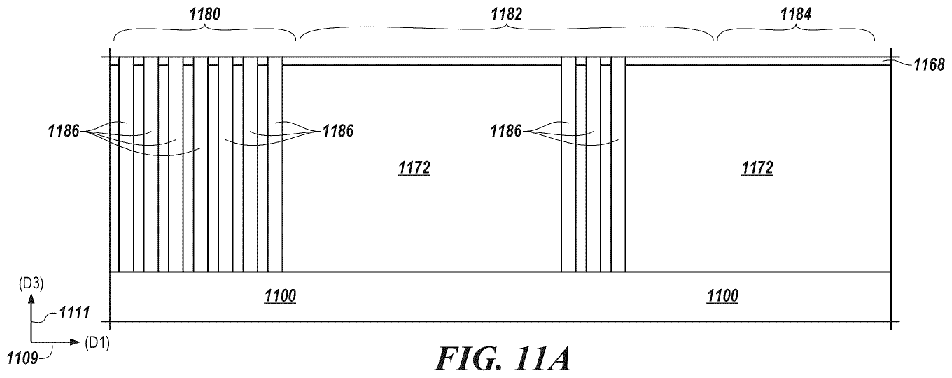

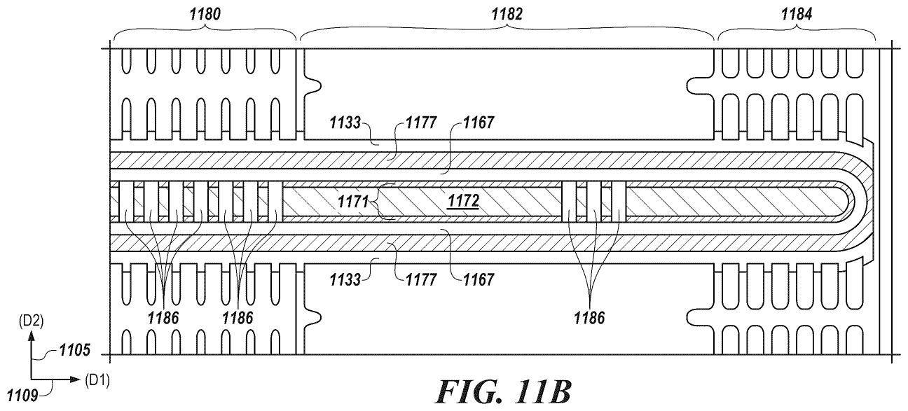

FIG. 11A illustrates an example method at another stage of a semiconductor fabrication process for forming a partition outside of a 3D memory array for a memory device, in accordance with a number of embodiments of the present disclosure. FIG. 11A is a cross sectional view as shown in FIG. 10A and illustrates a stage after the array region patterned 1078-1 first mask material 1076 of FIG. 10A was used to selectively remove, e.g., selectively etch, portions of the third conductive material 1072, e.g., doped silicon (Si) sense line material, in a vertical, e.g., third direction (D3) 1111, to define a plurality of spaced, vertical digit lines in the array region 1180 which are electrically connected to first source/drain regions, e.g., 923 shown in FIG. 9. The patterned first mask material 1076 in the patch isolation region 1078-2 of FIG. 10A was used to selectively remove, e.g., selectively etch, portions of the third conductive material 1072, e.g., doped silicon (Si) sense line material, in a vertical, e.g., third direction (D3) 1111, to define a plurality of spaced, vertical openings in the patch isolation region 1182. As shown in FIG. 11A, a selective etch process, e.g., timed selective etch process, may be used to remove the third conductive material 1172 in a vertical, e.g., third direction (D3) 1111, down through all memory cell layers until a substrate 1100 is reached. In some embodiments the third conductive material may be selectively removed to define an opening depth of 1000 nanometers or more, having an aspect ratio of depth/width of 10 or greater. Embodiments are not limited to this example. As shown in FIG. 11A, a fourth, selectably etchable dielectric material 1186, e.g., silicon oxide carbon (SOC) material, can be deposited in the plurality of spaced, vertical openings in the patch isolation region 1182 and the array region 1180, between the plurality of spaced, vertical sense lines, e.g., digit lines (DL). In some embodiments, the vertical columns of the fourth dielectric material 1186, e.g., SOC, can be deposited to a vertical height that is equal to the vertical height of the third conductive material 1172.

As illustrated in FIG. 11A, in some embodiments the number of vertical columns of fourth dielectric material 1186 in the array region 1180 can be different than the number of columns of fourth dielectric material 1186 in the patch isolation region 1182.

FIG. 11B illustrates cross sectional, top down view of an example method at the stage illustrated in FIG. 11A of a semiconductor fabrication process for forming a partition outside of a 3D memory array for a memory device, in accordance with a number of embodiments of the present disclosure. FIG. 11B is a cross sectional view as shown in FIG. 10B and illustrates a second dielectric material 1133, e.g., nitride, of a horizontally oriented access device, a first conductive material 1177 of an access device, and a third dielectric material 1167, which may be different from or the same as the second dielectric material 1133, of a horizontally oriented access device. Further, 11B illustrates a second conductive material 1171 of a vertically oriented sense line and a third conductive material 1172 of the vertically oriented sense line. FIG. 11B further illustrates a top down view of the vertical columns of the fourth dielectric material 1186 as described in connection with FIG. 11A.

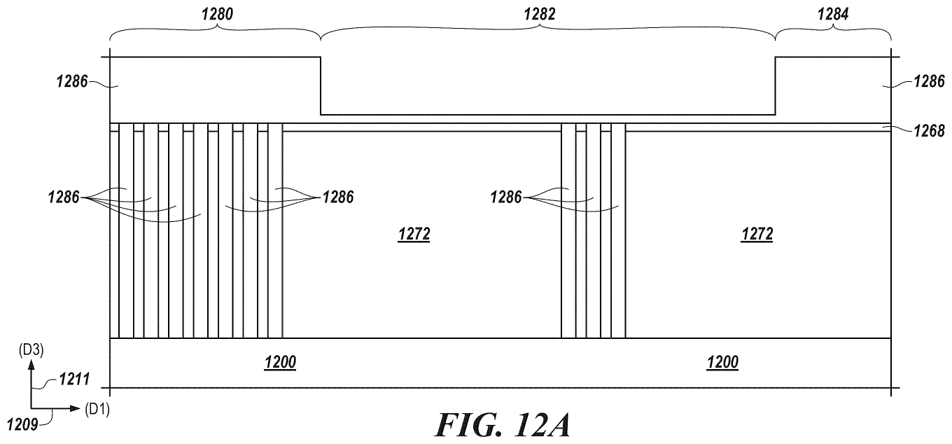

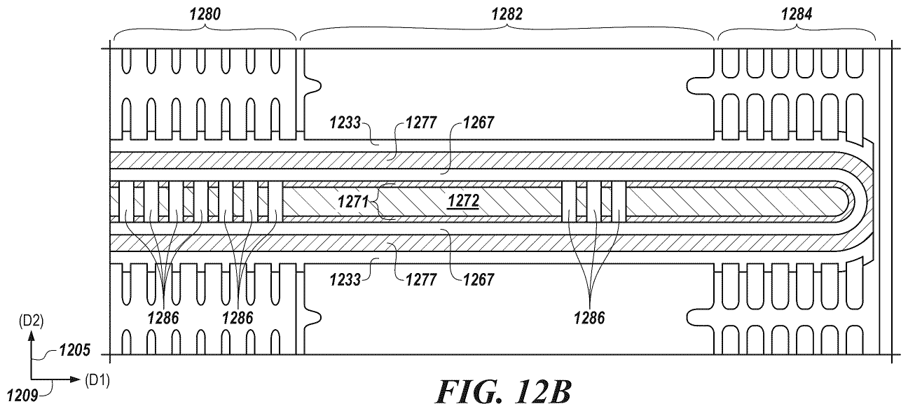

FIG. 12A illustrates an example method at another stage of a semiconductor fabrication process for forming a partition outside of a 3D memory array for a memory device, in accordance with a number of embodiments of the present disclosure. As shown in FIG. 12A, another deposition of the second dielectric material 1286 can be deposited over the structure, e.g., the third conductive material 1272 and the vertical columns of fourth dielectric 1286, patterned and removed from the patch isolation region 1282. In some embodiments, the additional deposited and removed dielectric material 1286 and the fourth dielectric material 1286 can be different materials and, in other embodiments, the deposited and patterned material 1286 and the fourth dielectric material 1286 can be the same, e.g., both SOC material.

As shown in FIG. 12A, the additionally deposited SOC material 1286 has been removed from over the patch isolation region 1282. The additionally deposited SOC material 1286 may remain over the array region 1284 and the array region 1280.

FIG. 12B illustrates a top down view of an example method at the stage illustrated in FIG. 12A of a semiconductor fabrication process for forming a partition outside of a 3D memory array for a memory device, in accordance with a number of embodiments of the present disclosure. FIG. 12B is a cross sectional view as shown in FIG. 10B and illustrates a second dielectric material 1233 of a horizontally oriented access device, a first conductive material 1277 of an access device, and a third dielectric material 1267 of a horizontally oriented access device. Further, 12B illustrates a second conductive material 1271 of a vertically oriented sense line and a third conductive material 1272 of the vertically oriented sense line. FIG. 12B further illustrates a top down view of the vertical columns of the fourth dielectric material 1286 as described in connection with FIG. 12A.

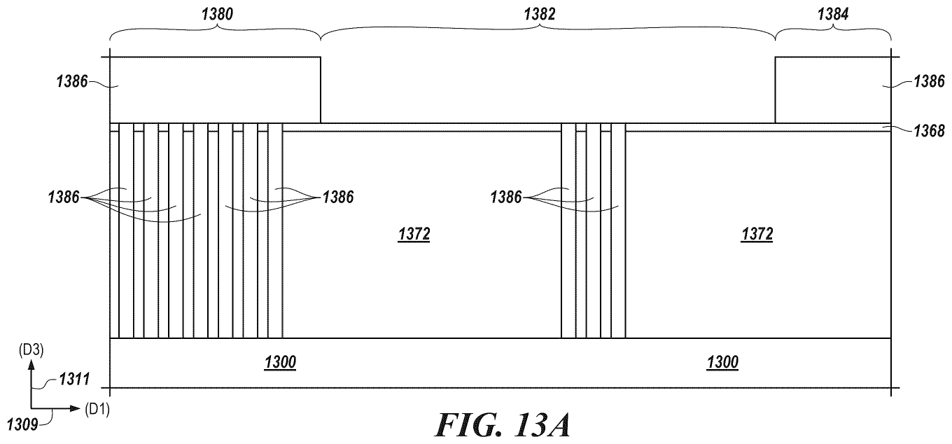

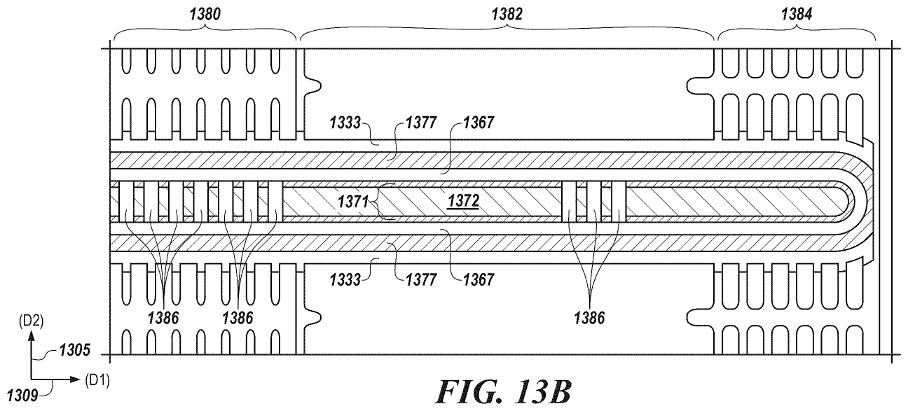

FIG. 13A illustrates an example method at another stage of a semiconductor fabrication process for forming a partition outside of a 3D memory array for a memory device, in accordance with a number of embodiments of the present disclosure. As shown in FIG. 13A, the additionally deposited fourth dielectric material (e.g., SOC material) 1386 over the patch isolation region 1382 can be removed from the patch isolation region 1382 using an etching process. In some embodiments, as shown in FIG. 13A, removing the additionally deposited SOC material 1386 can expose the third conductive material 1372 and the vertical columns of fourth dielectric material 1386 in the patch isolation region 1382. In some embodiments removing the additionally deposited SOC material 1386 may expose a dielectric material 1368, e.g., nitride, in the patch isolation region 1382. In some embodiments, a dry etch process may be used to remove the dielectric material 1368 and expose the vertical columns of second dielectric material 1376 in the patch isolation region 1382.

FIG. 13B illustrates a top down view of an example method at the stage illustrated in FIG. 13A of a semiconductor fabrication process for forming a partition outside of a 3D memory array for a memory device, in accordance with a number of embodiments of the present disclosure. FIG. 13B is a cross sectional view as shown in FIG. 10B and illustrates a second dielectric material 1333 of a horizontally oriented access device, a first conductive material 1377 of a horizontally oriented access device, and a third dielectric material 1367 of a horizontally oriented access device. Further, 13B illustrates a second conductive material 1371 of a vertically oriented sense line and a third conductive material 1372 of the vertically oriented sense line. FIG. 13B further illustrates a top down view of the vertical columns of the fourth dielectric material 1386 as described in connection with FIG. 13A.

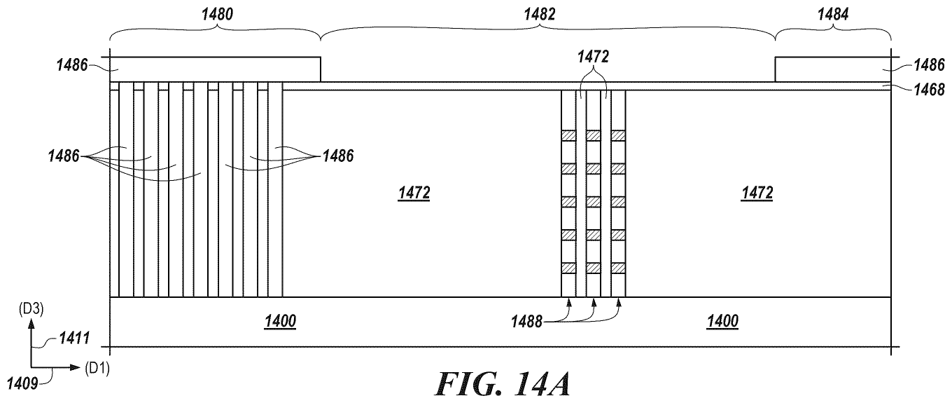

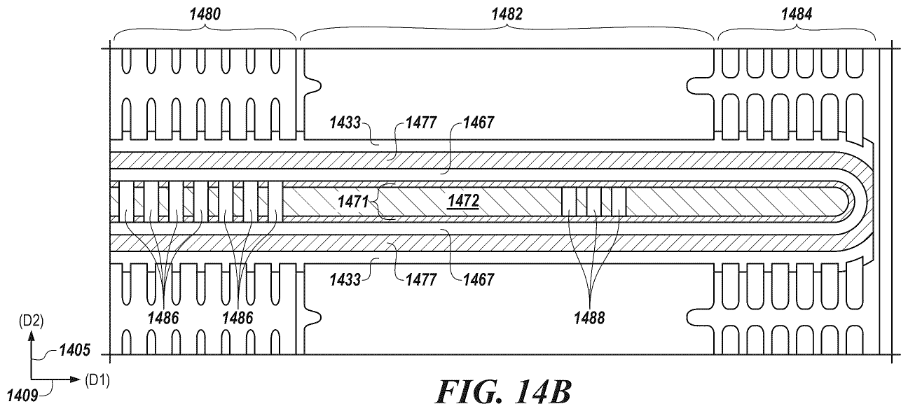

FIG. 14A is a cross sectional view as shown in FIG. 10A and illustrates an example method at another stage of a semiconductor fabrication process for forming a partition outside of a 3D memory array for a memory device, in accordance with a number of embodiments of the present disclosure. As shown in FIG. 14A, the fourth dielectric material (e.g., dielectric material 1386 in the patch isolation region 1382 in FIG. 13A) can be removed to form spaced vertical columns of the third conductive material 1472 in the patch isolation region 1482. The area in the patch isolation region 1482 from which portions of the third conductive material 1472 were removed can create openings 1488 which expose the horizontally oriented access devices formed in the patch isolation region 1482. In some embodiments the fourth dielectric material 1486 can be removed to form the vertical columns of third conductive material 1472 in the patch isolation region 1482 using a silicon oxide carbon wet strip etch process. Embodiments are not limited to this example.

In some embodiments, the etching process used to remove the portions of the third conductive material 1472 and the fourth dielectric material 1486 in the patch isolation region 1482 in FIG. 14A can remove a portion of the fourth material 1486 in the array region 1480 and the array region 1484. As shown in FIG. 14A, a remaining vertical thickness of the fourth dielectric material 1486 can be less than the vertical thickness of the fourth dielectric material 1386 shown in FIG. 13A, which illustrates a stage of the method that occurred before the wet etch that occurs during the current step of the method illustrated in FIG. 14A.

FIG. 14B illustrates a top down view of an example method at the stage illustrated in FIG. 14A of a semiconductor fabrication process for forming a partition outside of a 3D memory array for a memory device, in accordance with a number of embodiments of the present disclosure. FIG. 14B illustrates a second dielectric material 1433 of a horizontally oriented access device, a first conductive material 1477 of a horizontally oriented access device, and a third dielectric material 1467 of a horizontally oriented access device. Further, 14B illustrates a second conductive material 1471, and a third conductive material 1472 of the vertically oriented sense line, e.g., in a multi-layer sense line. FIG. 14B further illustrates a top down view of the vertical openings 1488 creating a plurality of separations to the third conductive material 1472 in the patch isolation region 1482.

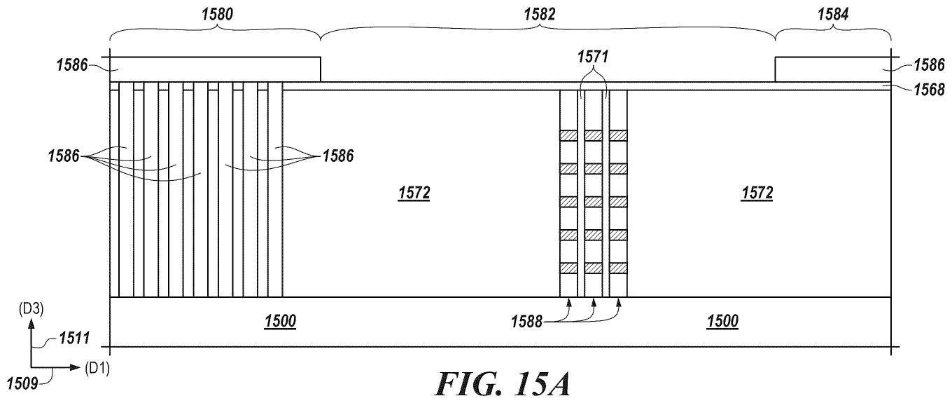

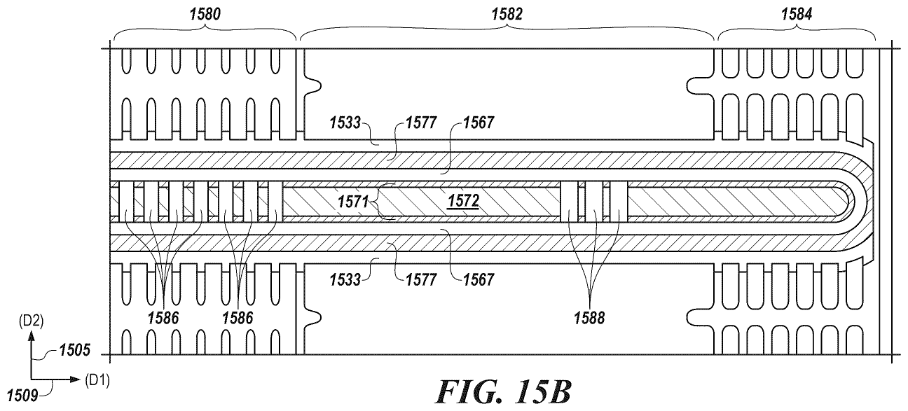

FIG. 15A is a cross sectional view as shown in FIG. 10A and illustrates an example method at another stage of a semiconductor fabrication process for forming a partition outside of a 3D memory array for a memory device, in accordance with a number of embodiments of the present disclosure. The stage of the method illustrated in FIG. 15A can include selectively removing additional ones of the spaced vertical columns of the third conductive material 1572 in the patch isolation region 1582. In some embodiments, the additional ones of the spaced vertical columns of the third conductive material 1572 can refer to the spaced vertical columns of the third conductive material 1572 in the patch isolation region 1582 that remain after the etch illustrated in FIG. 14A which created openings 1588. In some embodiments, selectively removing the additional ones of the spaced vertical columns of third conductive material 1572 can include performing a silicon (Si) wet etch, e.g., using a wet etch chemistry with or without a patterned mask material to selectively remove additional ones of the spaced vertical columns of third conductive material 1572 in the patch isolation region 1582. As illustrated in FIG. 15A, removing the additional ones of the spaced vertical columns of third conductive material 1572 in the patch isolation region 1582 can expose spaced vertical columns of the second conductive material 1571 in the patch isolation region 1582.

FIG. 15B is a cross sectional view as shown in FIG. 10B and illustrates a top down view of an example method at the stage illustrated in FIG. 15A of a semiconductor fabrication process for forming a partition outside of a 3D memory array for a memory device, in accordance with a number of embodiments of the present disclosure. The top down view illustrated in FIG. 15B does not include the first mask material 1576 illustrated in FIG. 15A. FIG. 15B illustrates a second dielectric material 1533 of a horizontally oriented access device, a first conductive material 1577 of a horizontally oriented access device, and a third dielectric material 1567 of a horizontally oriented access device. Further, 15B illustrates a second conductive material 1571 of a vertically oriented sense line and a third conductive material 1572 of the vertically oriented sense line. FIG. 15B further illustrates a top down view of the vertical columns of the first mask material 1576 in the array region 1580 and openings 1588 in the patch isolation region 1582 as described in connection with FIG. 15A.

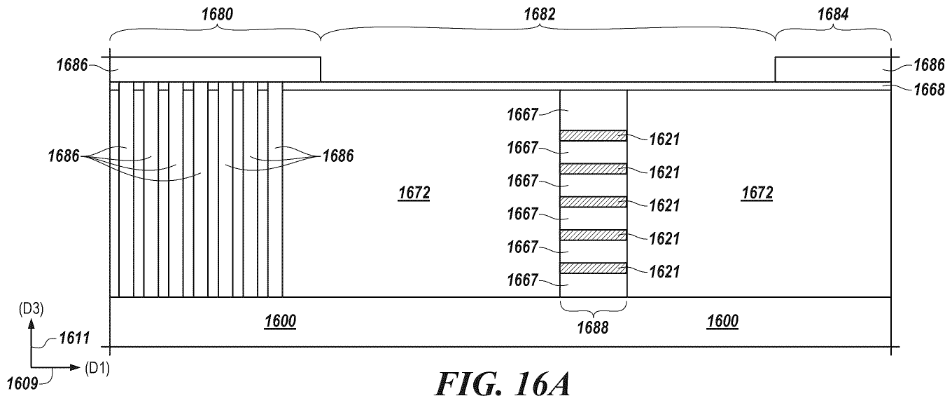

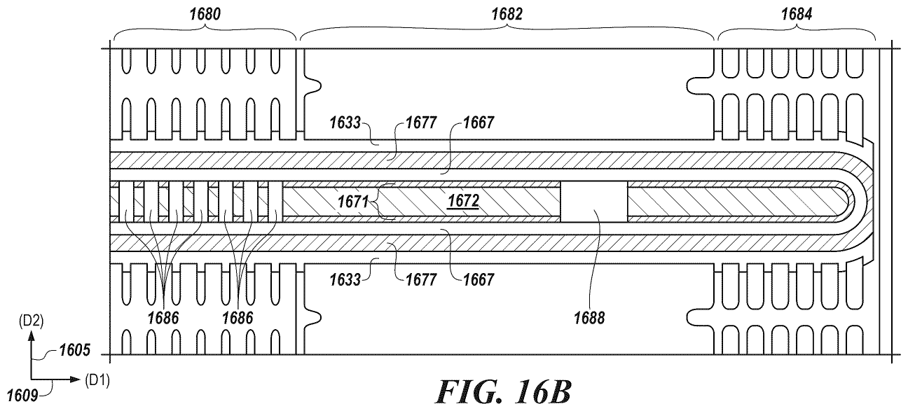

FIG. 16A is a cross sectional view as shown in FIG. 10A and illustrates an example method at another stage of a semiconductor fabrication process for forming a partition outside of a 3D memory array for a memory device, in accordance with a number of embodiments of the present disclosure. The stage of the method illustrated in FIG. 16A can include selectively removing spaced vertical columns of the second conductive material (e.g., second conductive material 1571 in FIG. 15A) in the patch isolation region 1682. In some embodiments, removing the spaced vertical columns of the second conductive material in the patch isolation region 1682 defines opening 1688. In some embodiments, the spaced vertical columns of the second conductive material in the patch isolation region 1682 can be removed using a wet etch chemistry. For example, in embodiments where the second conductive material (1571 in FIG. 5A) is a titanium nitride (TiN) material a TiN wet etch process may be used. As illustrated in FIG. 16A, removing the spaced vertical columns of the second conductive material in the patch isolation region 1682 can expose alternating layers of the third dielectric material 1667 capping the continuous horizontal access lines in the patch isolation region 1682.

FIG. 16B is a cross sectional view as shown in FIG. 10B and illustrates a top down view of an example method at the stage illustrated in FIG. 16A of a semiconductor fabrication process for forming a partition outside of a 3D memory array for a memory device, in accordance with a number of embodiments of the present disclosure. The top down view illustrated in FIG. 16B does not include the first mask material 1676 illustrated in FIG. 16A. FIG. 16B illustrates a second dielectric material 1633 of a horizontally oriented access device, a first conductive material 1677 of a horizontally oriented access device, and the third dielectric material 1667 of a horizontally oriented access device, exposed in the opening 1688 in the patch isolation region 1682. Further, 16B illustrates a second conductive material 1671 of a vertically oriented sense line and a third conductive material 1672 of the vertically oriented sense line elsewhere. FIG. 16B further illustrates a top down view of the vertical columns of the fourth dielectric material 1686 in the array region 1680 and opening 1688 in the patch isolation region 1682 as described in connection with FIG. 16A.

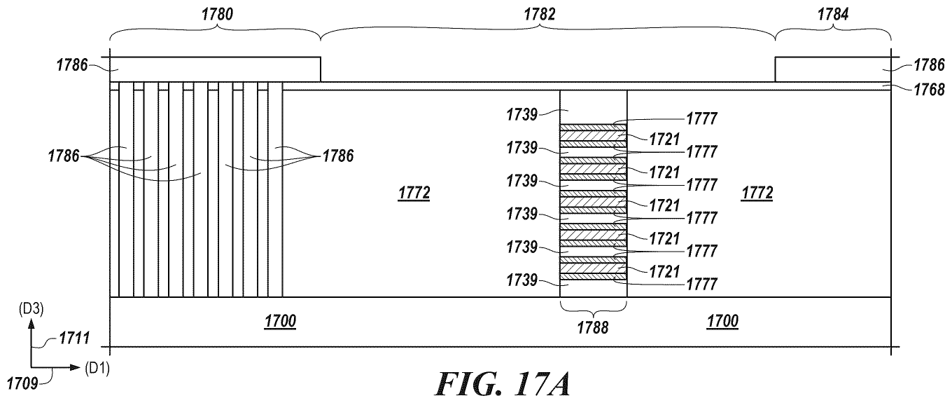

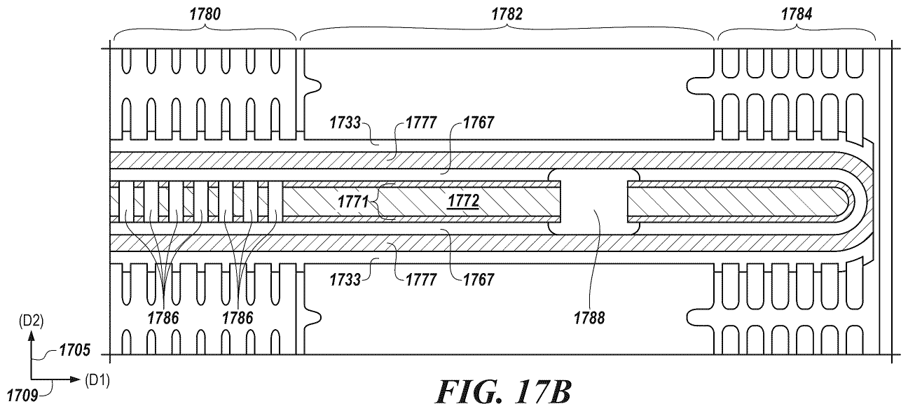

FIG. 17A is a cross sectional view as shown in FIG. 10A and illustrates an example method at another stage of a semiconductor fabrication process for forming a partition outside of a 3D memory array for a memory device, in accordance with a number of embodiments of the present disclosure. The stage of the method illustrated in FIG. 17A can include selectively removing the third dielectric material (e.g., third dielectric material 1667 in FIG. 16A) in the patch isolation region 1782. In some embodiments, a wet etch chemistry can be used to remove the third dielectric material in the patch isolation region 1782. For example, in embodiments in which the third dielectric material is an oxide, an oxide wet etch process can be used to remove the third dielectric material and expose the continuous horizontal access lines 1777 in the opening 1788 in the patch isolation region 1782. In some embodiments, the wet etch chemistry can be deposited in the patch isolation region 1782 through opening 1788. Hence, removing the third dielectric material exposes the first conductive material 1777 of continuous horizontal access lines extending into the patch isolation region from the horizontally oriented access devices in the patch isolation region 1782 at the opening 1788.

FIG. 17B is a cross sectional view as shown in FIG. 10B and illustrates a top down view of an example method at the stage illustrated in FIG. 17A of a semiconductor fabrication process for forming a partition outside of a 3D memory array for a memory device, in accordance with a number of embodiments of the present disclosure. The top down view illustrated in FIG. 17B does not include first mask material 1776 illustrated in FIG. 17A. FIG. 17B illustrates a second dielectric material 1733 of a horizontally oriented access device, a first conductive material 1777 of a horizontally oriented access device, and a third dielectric material 1767 of a horizontally oriented access device. Further, 17B illustrates a second conductive material 1771 of a vertically oriented sense line and a third conductive material 1772 of the vertically oriented sense line. FIG. 17B further illustrates a top down view of the vertical columns of the fourth dielectric material 1786 in the array region 1780 and the third dielectric material removed in the opening 1788 in the patch isolation region 1782 as described in connection with FIG. 17A.

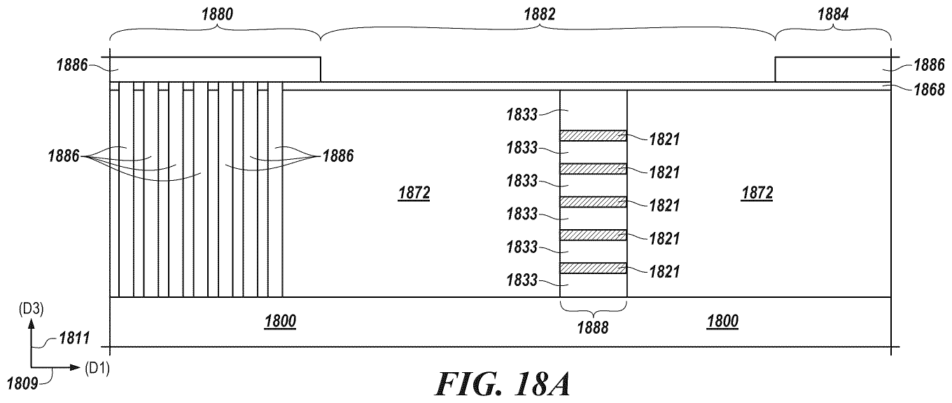

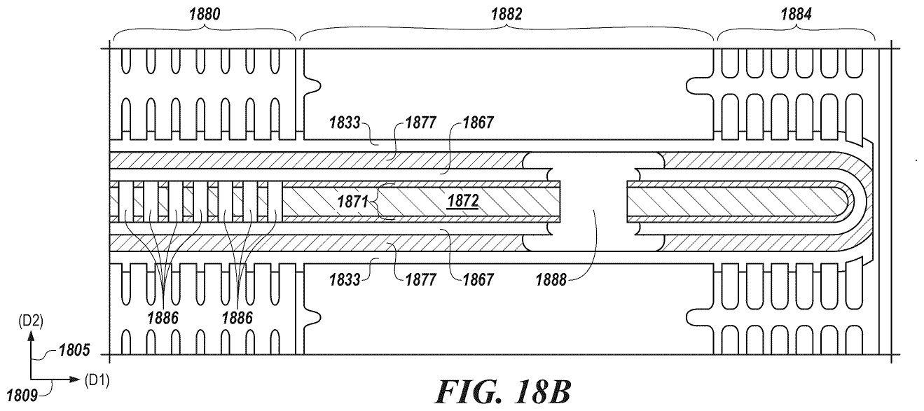

FIG. 18A is a cross sectional view as shown in FIG. 10A and illustrates an example method at another stage of a semiconductor fabrication process for forming a partition outside of a 3D memory array for a memory device, in accordance with a number of embodiments of the present disclosure. The stage of the method illustrated in FIG. 18A can include selectively removing the first conductive material (e.g., first conductive material 1777 in FIG. 17A) from the opening 1888 in the patch isolation region 1882. In some embodiments, a wet etch chemistry can be used to remove the first conductive material from the opening 1888 in the patch isolation region 1882. For example, in embodiments in which the first conductive material is a titanium nitride (TiN) material, a TiN wet etch chemistry process can be performed in the patch isolation region 1882 through opening 1888. In some embodiments, removing the first conductive material can expose the second dielectric material 1833 extending from the horizontally oriented access devices into the patch isolation region 1882.

FIG. 18B is a cross sectional view as shown in FIG. 10B and illustrates a top down view of an example method at the stage illustrated in FIG. 18A of a semiconductor fabrication process for forming a partition outside of a 3D memory array for a memory device, in accordance with a number of embodiments of the present disclosure. The top down view illustrated in FIG. 18B does not include the first mask material 1876 illustrated in FIG. 18A. FIG. 18B illustrates a second dielectric material 1833 of a horizontally oriented access device, a first conductive material 1877 of the horizontally oriented access device, and a third dielectric material 1867 of a horizontally oriented access device. Further, 18B illustrates a second conductive material 1871 of a vertically oriented sense line and a third conductive material 1872 of the vertically oriented sense line, e.g., in a multi-layer sense line extension from the array region 1880. FIG. 18B further illustrates a top down view of the vertical columns of the fourth dielectric material 1886 in the array region 1880 and the first conductive material and the third dielectric material removed in the opening 1888 in the patch isolation region 1882 as described in connection with FIG. 18A.

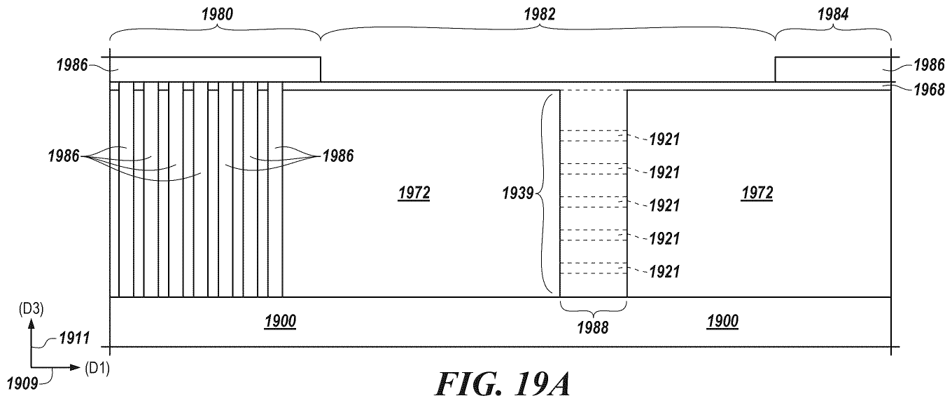

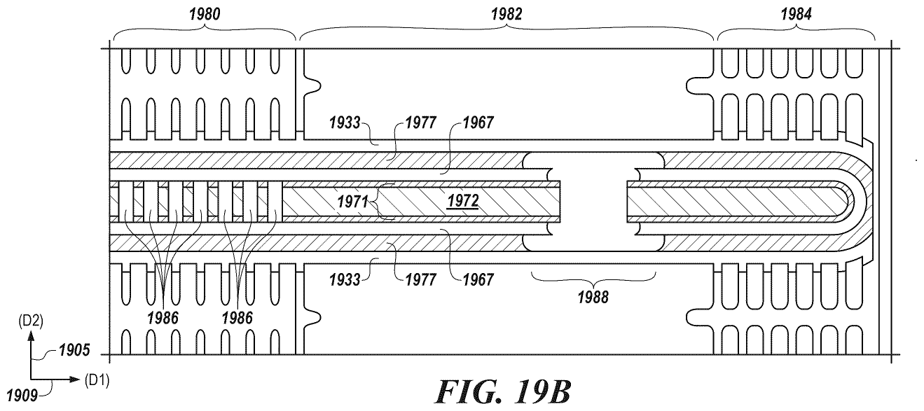

FIG. 19A is a cross sectional view as shown in FIG. 10A and illustrates an example method at another stage of a semiconductor fabrication process for forming a partition outside of a 3D memory array for a memory device, in accordance with a number of embodiments of the present disclosure. The stage of the method illustrated in FIG. 19A can include replacing the removed portions of the continuous horizontal access lines with a first dielectric material 1939 in the patch isolation region 1982. In some embodiments, the first dielectric material 1939 can be a same dielectric material as the second dielectric material 1933 and/or third dielectric material, e.g., nitride, and be deposited in the patch isolation region 1982 through the opening 1988 to fill the opening 1988.

Depositing the first dielectric material 1939 in the patch isolation region 1982 can separate the continuous horizontal access lines 1977 extending into the patch isolation region 1982 from the array region 1980 and can passivate the continuous horizontal access line material 1977 in the patch isolation region 1982. The term “passivate” refers to making a metal material unreactive. In some embodiments, depositing the first dielectric material 1939 in the patch isolation region 1982 can electrically isolate the array region 1980 from the array region 1984.

FIG. 19B is a cross sectional view as shown in FIG. 10B and illustrates a top down view of an example method at the stage illustrated in FIG. 19A of a semiconductor fabrication process for forming a partition outside of a 3D memory array for a memory device, in accordance with a number of embodiments of the present disclosure. The top down view illustrated in FIG. 19B does not include fourth dielectric material 1986 illustrated in FIG. 19A. FIG. 19B illustrates a first dielectric material 1933 of a horizontally oriented access device, a first conductive material 1977 of a horizontally oriented access device, and a third dielectric material 1967 of a horizontally oriented access device. Further, 19B illustrates a second conductive material 1971 of a vertically oriented sense line and a third conductive material 1972 of the vertically oriented sense line, separated in an array region 1980. FIG. 19B further illustrates a top down view of the vertical columns of the fourth dielectric material 1986 in the array region 1982 and first dielectric material 1939 in the patch isolation region 1982 separating the continuous horizontal access lines 1977 extending into the patch isolation region 1982 from the array region 1980 as described in connection with FIG. 19A.

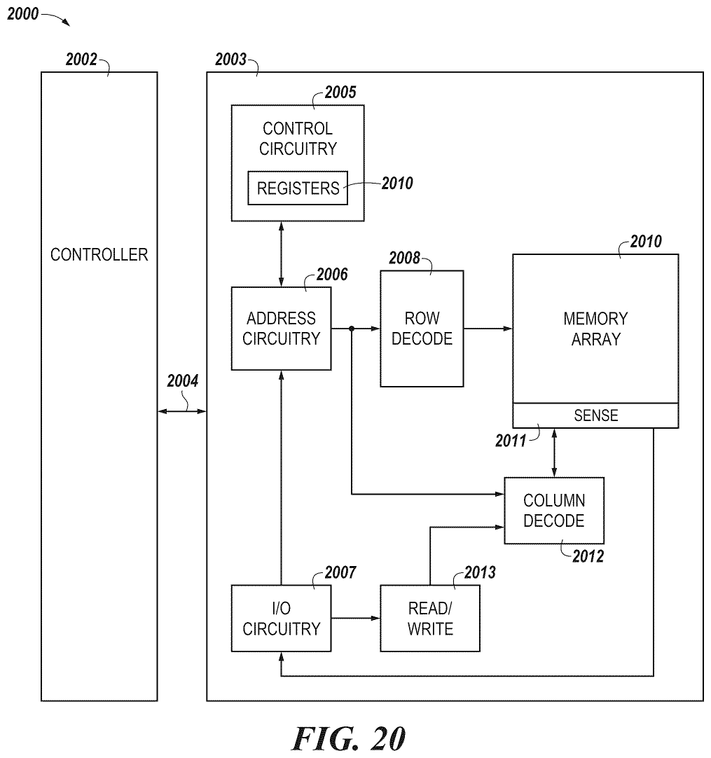

FIG. 20 is a block diagram of an apparatus in the form of a computing system 2000 including a memory device 2003 in accordance with a number of embodiments of the present disclosure. As used herein, a memory device 2003, a memory array 2010, and/or a host 2002, for example, might also be separately considered an “apparatus.” According to embodiments, the memory device 2003 may comprise at least one memory array 2010 with a memory cell formed having a digit line and body contact, according to the embodiments described herein.

In this example, system 2000 includes a host 2002 coupled to memory device 2003 via an interface 2004. The computing system 2000 can be a personal laptop computer, a desktop computer, a digital camera, a mobile telephone, a memory card reader, or an Internet-of-Things (IoT) enabled device, among various other types of systems. Host 2002 can include a number of processing resources (e.g., one or more processors, microprocessors, or some other type of controlling circuitry) capable of accessing memory 2003. The system 2000 can include separate integrated circuits, or both the host 2002 and the memory device 2003 can be on the same integrated circuit. For example, the host 2002 may be a system controller of a memory system comprising multiple memory devices 2003, with the system controller 2005 providing access to the respective memory devices 2003 by another processing resource such as a central processing unit (CPU).

In the example shown in FIG. 20, the host 2002 is responsible for executing an operating system (OS) and/or various applications (e.g., processes) that can be loaded thereto (e.g., from memory device 2003 via controller 2005). The OS and/or various applications can be loaded from the memory device 2003 by providing access commands from the host 2002 to the memory device 2003 to access the data comprising the OS and/or the various applications. The host 2002 can also access data utilized by the OS and/or various applications by providing access commands to the memory device 2003 to retrieve said data utilized in the execution of the OS and/or the various applications.

For clarity, the system 2000 has been simplified to focus on features with particular relevance to the present disclosure. The memory array 2010 can be a DRAM array comprising at least one memory cell having a digit line and body contact formed according to the techniques described herein. For example, the memory array 2010 can be an unshielded DL 4F2 array such as a 3D-DRAM memory array. The array 2010 can comprise memory cells arranged in rows coupled by word lines (which may be referred to herein as access lines or select lines) and columns coupled by digit lines (which may be referred to herein as sense lines or data lines). Although a single array 2010 is shown in FIG. 20, embodiments are not so limited. For instance, memory device 2003 may include a number of arrays 2010 (e.g., a number of banks of DRAM cells).

The memory device 2003 includes address circuitry 2006 to latch address signals provided over an interface 2004. The interface can include, for example, a physical interface employing a suitable protocol (e.g., a data bus, an address bus, and a command bus, or a combined data/address/command bus). Such protocol may be custom or proprietary, or the interface 2004 may employ a standardized protocol, such as Peripheral Component Interconnect Express (PCIe), Gen-Z, CCIX, or the like. Address signals are received and decoded by a row decoder 2008 and a column decoder 2012 to access the memory array 2010. Data can be read from memory array 2010 by sensing voltage and/or current changes on the sense lines using sensing circuitry 2011. The sensing circuitry 2011 can comprise, for example, sense amplifiers that can read and latch a page (e.g., row) of data from the memory array 2010. The I/O circuitry 2007 can be used for bi-directional data communication with the host 2002 over the interface 2004. The read/write circuitry 2013 is used to write data to the memory array 2010 or read data from the memory array 2010. As an example, the circuitry 2013 can comprise various drivers, latch circuitry, etc.

Control circuitry 2005 decodes signals provided by the host 2002. The signals can be commands provided by the host 2002. These signals can include chip enable signals, write enable signals, and address latch signals that are used to control operations performed on the memory array 2010, including data read operations, data write operations, and data erase operations. In various embodiments, the control circuitry 2005 is responsible for executing instructions from the host 2002. The control circuitry 2005 can comprise a state machine, a sequencer, and/or some other type of control circuitry, which may be implemented in the form of hardware, firmware, or software, or any combination of the three. In some examples, the host 2002 can be a controller external to the memory device 2003. For example, the host 2002 can be a memory controller which is coupled to a processing resource of a computing device.

The term semiconductor can refer to, for example, a material, a wafer, or a substrate, and includes any base semiconductor structure. “Semiconductor” is to be understood as including silicon-on-sapphire (SOS) technology, silicon-on-insulator (SOI) technology, thin-film-transistor (TFT) technology, doped and undoped semiconductors, epitaxial silicon supported by a base semiconductor structure, as well as other semiconductor structures. Furthermore, when reference is made to a semiconductor in the preceding description, previous process steps may have been utilized to form regions/junctions in the base semiconductor structure, and the term semiconductor can include the underlying materials containing such regions/junctions.

The figures herein follow a numbering convention in which the first digit or digits correspond to the drawing figure number and the remaining digits identify an element or component in the drawing. Similar (e.g., the same) elements or components between different figures may be identified by the use of similar digits. As will be appreciated, elements shown in the various embodiments herein can be added, exchanged, and/or eliminated so as to provide a number of additional embodiments of the present disclosure. In addition, as will be appreciated, the proportion and the relative scale of the elements provided in the figures are intended to illustrate the embodiments of the present disclosure and should not be taken in a limiting sense.

As used herein, “a number of” or a “quantity of” something can refer to one or more of such things. For example, a number of or a quantity of memory cells can refer to one or more memory cells. A “plurality” of something intends two or more. As used herein, multiple acts being performed concurrently refers to acts overlapping, at least in part, over a particular time period. As used herein, the term “coupled” may include electrically coupled, directly coupled, and/or directly connected with no intervening elements (e.g., by direct physical contact), indirectly coupled and/or connected with intervening elements, or wirelessly coupled. The term coupled may further include two or more elements that co-operate or interact with each other (e.g., as in a cause and effect relationship). An element coupled between two elements can be between the two elements and coupled to each of the two elements.

It should be recognized the term vertical accounts for variations from “exactly” vertical due to routine manufacturing, measuring, and/or assembly variations and that one of ordinary skill in the art would know what is meant by the term “perpendicular.” For example, the vertical can correspond to the z-direction. As used herein, when a particular element is “adjacent to” another element, the particular element can cover the other element, can be over the other element or lateral to the other element and/or can be in direct physical contact with the other element. Lateral to may refer to the horizontal direction (e.g., the y-direction or the x-direction) that may be perpendicular to the z-direction, for example.

Although specific embodiments have been illustrated and described herein, those of ordinary skill in the art will appreciate that an arrangement calculated to achieve the same results can be substituted for the specific embodiments shown. This disclosure is intended to cover adaptations or variations of various embodiments of the present disclosure. It is to be understood that the above description has been made in an illustrative fashion, and not a restrictive one. Combination of the above embodiments, and other embodiments not specifically described herein will be apparent to those of skill in the art upon reviewing the above description. The scope of the various embodiments of the present disclosure includes other applications in which the above structures and methods are used. Therefore, the scope of various embodiments of the present disclosure should be determined with reference to the appended claims, along with the full range of equivalents to which such claims are entitled.

What is claimed is:

1. A method for a vertically stacked 3D memory array, comprising:
forming horizontally oriented access devices and horizontally oriented storage nodes in a plurality of levels as memory cells in the vertically stacked 3D memory array, the vertically stacked 3D memory array having continuous, conductive horizontal access lines at each level which serve as gates at channel regions separating first and second source/drain regions of the horizontal access devices;
forming a first vertical opening through the vertically stacked 3D memory array extending predominantly in a first horizontal direction to expose first vertical sidewalls in the 3D memory array;
depositing a doped silicon (Si) material in the first vertical opening to fill the first vertical opening;
selectively removing portions of the doped Si material in an array region to form a plurality of spaced, vertical digit lines in the array region that are electrically connected to the first source/drain regions;
selectively removing portions of the doped Si in a patch isolation region separating the array region from a peripheral component region of the vertically stacked 3D memory array;
selectively removing portions of the continuous horizontal access lines in the patch isolation region; and
replacing the removed portions of the continuous horizontal access lines with a first dielectric material in the patch isolation region.

2. The method of claim 1, wherein selectively removing portions of the doped Si in the patch isolation region, comprises:
concurrently patterning a first mask above the array region and the patch isolation region;
using the patterned first mask to selectively remove portions of the doped Si in the array region and the patch isolation region to form spaced vertical columns of doped Si, wherein the vertical columns of doped Si are electrically coupled to the first source/drain regions in the array region; and
depositing a second dielectric between the spaced vertical columns of doped Si.

3. The method of claim 2, wherein selectively removing portions of the doped Si in the patch isolation region, comprises:
separately patterning a second mask above the patch isolation region; and
using a wet etch chemistry through the patterned second mask to selectively remove additional ones of the spaced vertical columns of doped Si material in the patch isolation region.

4. The method of claim 3, wherein forming horizontally oriented access devices and horizontally oriented storage nodes, comprises:
forming horizontally oriented access devices and horizontally oriented storage nodes in alternating layers of silicon (Si) and silicon germanium (SiGe) material, the alternating layers together creating the plurality of levels of memory cells.

5. The method of claim 4, wherein forming the horizontally oriented access devices and the horizontally oriented storage nodes at each level of the vertically stacked 3D memory array comprises:
forming a plurality of second vertical openings, through the array region, the second vertical openings extending predominantly in the second horizontal direction separating memory cells on each level of memory cells; and
filling the plurality of second vertical openings with the second dielectric material; and
before depositing the doped silicon (Si) material in the first vertical opening, doping first source/drain regions of the alternating Si layers through the first vertical opening.

6. The method of claim 5, further comprising:
before depositing the doped silicon (Si) material in the first vertical opening, selectively etching the silicon germanium (SiGe) layers, and reducing a vertical thickness of the Si layers to form a plurality of first horizontal openings a first length (L1) from the first vertical opening;
conformally depositing the first dielectric material on exposed surfaces in the plurality of first horizontal openings;
recessing the first dielectric material to expose the first source/drain regions to the first vertical opening;
depositing the second dielectric material to fill the plurality of first horizontal openings;
selectively etching the first dielectric material from the plurality of first horizontal openings a second length (L2) from the first vertical opening;
selectively removing the second dielectric material between memory cells on each level;
forming a gate dielectric material on exposed surfaces of the reduced vertical thickness of the Si layers;
depositing a first conductive material on the Si layers to form gate all around (GAA) structures at the channel regions of the access devices;
recessing the first conductive material to the channel regions; and
depositing a third dielectric material to fill the plurality of first horizontal openings from the first conductive material to the first vertical opening.

7. The method of claim 6, wherein depositing the first conductive material on the Si layers to form the gate all around (GAA) structures comprises forming continuous conductive horizontal access lines at each level.

8. The method of claim 6, wherein forming the horizontally oriented storage nodes at each level of the vertically stacked 3D memory array, comprises:
forming third vertical openings extending in the first horizontal direction adjacent a second region of the alternating layers of SiGe material and Si material to expose third vertical sidewalls in the vertical stack;
selectively etching the Si and SiGe material in the second horizontal direction to form second horizontal openings in the second region;
gas phase doping a dopant in a side surface of the silicon (Si) material in the second horizontal openings to form second source/drain regions horizontally adjacent the channel regions; and
depositing horizontally oriented capacitor cells having a bottom electrode in electrical contact with the second source/drain regions.

9. The method of claim 1, wherein selectively removing portions of the continuous horizontal access lines in the patch isolation region comprises using a wet etch chemistry to horizontally remove conductive access line material in the patch isolation region.

10. The method of claim 1, wherein the method includes forming the vertical digit lines in the array region by flowing a tungsten hexafluoride material over exposed surfaces of the doped Si material to form bi-layer vertical digit lines in the array region.

11. The method of claim 10, wherein forming the bi-layer vertical digit lines in the array region comprises forming bi-layer vertical digit lines having an outer layer of tungsten and an inner layer of doped Si material.

12. A method for a vertically stacked 3D memory array, comprising:
forming horizontally oriented access devices and horizontally oriented storage nodes in a plurality of levels as memory cells in the vertically stacked 3D memory array, the vertically stacked 3D memory array having channel regions separating first and second source/drain regions of the horizontally oriented access devices;
forming a first vertical opening through the vertically stacked 3D memory array extending predominantly in a first horizontal direction to expose first vertical sidewalls in the vertically stacked 3D memory array;
forming conductive horizontal access lines at each level which serve as gates at channel regions and extend continuously in an array region and into a patch isolation region which separates the array region from a peripheral component region;
depositing a doped silicon (Si) material in the first vertical opening to fill the first vertical opening;
concurrently patterning a first mask above the array region and the patch isolation region;
using the patterned first mask to selectively remove portions of the doped Si in the array region and the patch isolation region to form spaced vertical columns of doped Si, wherein the vertical columns of doped silicon are electrically coupled to the first source/drain regions in the array region;
depositing a first dielectric between the spaced vertical columns of doped Si;
selectively removing additional portions of the doped Si in the patch isolation region;
selectively removing portions of the continuous horizontal access lines in the patch isolation region; and
replacing the removed portions of the continuous horizontal access lines with a second dielectric material (nitride) in the patch isolation region.

13. The method of claim 12, wherein the second dielectric material is a silicon nitride (SiN) material.

14. The method of claim 12, wherein the second dielectric material is deposited through a second vertical opening formed by removing the additional portions of the doped Si in the patch isolation region.

15. The method of claim 12, further comprising passivating the patch isolation region by depositing the second dielectric material.

16. A memory device, comprising:
an array of vertically stacked memory cells, having a plurality of levels, each level of the array of vertically stacked memory cells having horizontally oriented access devices and horizontally oriented storage nodes, comprising:
the horizontally oriented access devices having first source/drain regions and second source/drain regions separated by channels; and
the horizontally oriented storage nodes electrically connected to the second source/drain regions of the horizontally oriented access devices;
a plurality of conductive horizontal access lines at each level which serve as gates at channel regions and extend continuously in a first direction in an array region and into a patch isolation region which separates the array region from a peripheral component region; and
a dielectric material separating the horizontal access lines on each level in the patch isolation region from the peripheral component region in a second direction and a third direction.

17. The memory device of claim 16, wherein the conductive horizontal access lines serve as gate all around (GAA) structures at the channel regions on each level.

18. The memory device of claim 16, further comprising vertical columns of spaced sense lines which are electrically coupled to the first source/drain regions in the array region.

19. The memory device of claim 18, where the vertical columns of spaced sense lines in the array region are bi-layer vertical sense lines having an outer layer of tungsten and an inner layer of doped Si material.

20. The memory device of claim 16, wherein the horizontally oriented storage nodes are double-sided capacitors.
